(19) United States
(12) Patent Application Publication
(10) Pub. No.: US 2026/0349565 A1
(43) Pub. Date: Nov. 5, 2026

(54) ELECTRONIC DEVICE AND PROXIMITY SENSING METHOD THEREOF

(71) Applicant: HiDeep Inc., Seongnam-si, Gyeonggi-do (KR)

(72) Inventors: Bonkee KIM, Seongnam-si, Gyeonggi-do (KR); Seyeob KIM, Seongnam-si, Gyeonggi-do (KR)

(73) Assignee: HiDeep Inc., Seongnam-si, Gyeonggi-do (KR)

(21) Appl. No.: 19/488,916

(22) PCT Filed: Apr. 30, 2024
(86) PCT No.: PCT/KR2024/005871

§ 371 Date: Dec. 1, 2025

(30) Foreign Application Priority Data
May 31, 2023 (KR) 10-2023-0070123

(51) Int. Cl. G06F 3/041; G06F 3/044

(52) U.S. Cl. CPC G06F 3/04184; G06F 3/0446; G06F 2203/04102; G06F 2203/04108

(57) ABSTRACT

An embodiment of the present invention relates to an electronic device and a proximity sensing method thereof, and, more specifically, to an electronic device and a proximity sensing method thereof, the device being capable of alleviating flickering on a display panel during proximity sensing and enhancing signal-to-noise ratio (SNR). The electronic device of the present invention comprises: a sensor including a plurality of driving electrodes and a plurality of reception electrodes arranged to intersect the plurality of driving electrodes; and a control unit which simultaneously drives the plurality of driving electrodes for a predetermined time for proximity sensing on a touch screen, and which detects the proximity of an object on the touch screen on the basis of sensing signals from the plurality of reception electrodes, wherein the control unit applies a positive (+) driving signal to some of the plurality of driving electrodes and applies a negative (−) driving signal to the remaining driving electrodes of the plurality of driving electrodes.

### TECHNICAL FIELD

The present invention relates to an electronic device and a proximity sensing method thereof, and more particularly, to an electronic device capable of improving occurrence of flicker in a display panel during proximity sensing and enhancing a signal-to-noise ratio (SNR) and a proximity sensing method thereof.

### BACKGROUND ART

Various kinds of input devices are used to operate a computing system. For example, the input devices such as a button, a key, a joystick, and a touch screen are used. Since the touch screen is easily and simply operated, the touch screen is increasingly used when operating the computing system.

A touch sensor that is one kind of information input devices may be provided in a display panel. For example, the touch sensor may be attached to one surface of the display panel or integrated with the display panel. A user may input information by touching the touch sensor while seeing an image displayed on a screen of the display panel.

FIG. 1 is a schematic view illustrating a laminated structure of a typical OCTA method.

The OCTA that is one kind of touch screen panel technologies stands for On Cell Touch AMOLED and is one kind of touch screen panels (TSP) obtained by directly depositing the touch sensor on an AMOLED display cell as illustrated in FIG. 1. That is, the OCTA is a technology of applying a touch screen function of a smartphone/tablet into an OLED panel. Since no tempered glass is used between the cell and the touch sensor, clarity is improved compared with a typical general TSP.

Y-OCTA is a touch screen panel obtained by directly depositing the touch sensor on the cell. The Y-OCTA is named by adding Y of ‘YOUM’ that is a brand name of Samsung display flexible OLED to the ‘OCTA’. The Y-OCTA technology is applied to a thin film encapsulation (TFE) process among OLED manufacturing processes. The touch screen is realized by patterning an aluminum metal mesh sensor used as the touch sensor between a polarizer and an organic material for thin film encapsulation. The Y-OCTA may resolve a visibility limitation occurring at a curved edge by attaching the polarizer closely to a cover window. Also, costs may be reduced by removing a support film to reduce a thickness of the panel and by omitting a laminating process.

Since an electronic device including a flexible display panel such as a conventional Y-OCTA touch screen panel has a reduced panel thickness, a distance between the display panel and the touch sensor decreases. Accordingly, since a sensing signal output from the touch sensor is easily influenced by driving of the display panel, there is a limitation in that the sensing signal is distorted by a display noise.

A conventional electronic device including a flexible display panel may perform proximity sensing or hover sensing. The proximity sensing is used to determine an operation in which a user brings an upper portion of a smartphone, on which a speaker of the smartphone is disposed, closely to an ear of the user when receiving a telephone call. When the upper portion of the smartphone is brought closely to the ear of the user, the smartphone senses the proximity and turns off the display screen of the display panel to prevent a touch operation from being performed by skin contact of the ear or cheek of the user.

However, when the conventional electronic device including the flexible display panel performs a proximity sensing or hover sensing operation, a magnitude of the sensing signal output from the touch sensor when an object is in proximity to the touch screen is extremely smaller than that of the sensing signal output when the object is brought into contact with the touch screen of the display panel. Thus, the proximity sensing is not easily distinguished. In particular, as a distance from the touch screen increases, a magnitude of a signal detected by the proximity sensing gradually decreases. Thus, the proximity sensing becomes even more difficult.

A conventional electronic device that solves the above-described limitations of the proximity sensing will be described with reference to the drawings.

FIG. 2 is a view illustrating a proximity sensing method of a conventional electronic device.

Referring to FIG. 2, the conventional electronic device may simply include a touch sensor 10 and a control unit 30.

The touch sensor 10 is disposed on a display panel (not shown) and includes a plurality of driving electrodes Tx0, Tx1, Tx2, Tx3 . . . Tx16, Tx17, Tx18, Tx19 and a plurality of receiving electrodes Rx0, Rx1, Rx2, Rx3 . . . Rx35, Rx36, Rx37, which are arranged to intersect each other.

A predetermined mutual capacitance cm is formed between the plurality of driving electrodes Tx0, Tx1, Tx2, Tx3 . . . Tx16, Tx17, Tx18, and Tx19 and the plurality of receiving electrodes Rx0, Rx1, Rx2, Rx3 . . . Rx35, Rx36, and Rx37, particularly at intersections thereof.

Each of the driving electrodes Tx0, Tx1, Tx2, Tx3 . . . Tx16, Tx17, Tx18, and Tx19 is arranged in a first axial direction (or vertical direction), and each of the receiving electrodes Rx0, Rx1, Rx2, Rx3 . . . Rx35, Rx36, and Rx37 is arranged in a second axial direction (or horizontal direction) different from the first axial direction. Here, the second axial direction may be perpendicular to the first axial direction. The first axial direction may be referred to as a major axis direction, and the second axial direction may be referred to as a minor axis direction.

Each of the driving electrodes Tx0, Tx1, Tx2, Tx3 . . . Tx16, Tx17, Tx18, and Tx19 has a length greater than that of each of the receiving electrodes Rx0, Rx1, Rx2, Rx3 . . . Rx35, Rx36, and Rx37. Also, the number of the plurality of driving electrodes Tx0, Tx1, Tx2, Tx3 . . . Tx16, Tx17, Tx18, and Tx19 is less than that of the plurality of receiving electrodes Rx0, Rx1, Rx2, Rx3 . . . Rx35, Rx36, and Rx37. This is because a vertical length is longer than a horizontal length in the display screen of the conventional electronic device. For example, the electronic device may be a smartphone.

The control unit 30 controls the touch sensor 10. Specifically, the control unit 30 applies a driving signal (or Tx signal) to a driving electrode (Tx electrode) of the touch sensor 10 and receives a sensing signal (or Rx signal) from a receiving electrode (Rx electrode) of the touch sensor 10.

The control unit 30 may sequentially apply driving signals to the plurality of driving electrodes Tx0, Tx1, Tx2, Tx3, Tx4, Tx17, Tx18, and Tx19 of the touch sensor 10 or simultaneously apply predetermined driving signals to some driving electrodes among the plurality of driving electrodes Tx0, Tx1, Tx2, Tx3, Tx4, Tx17, Tx18, and Tx19. The former is called as a sequential driving method, and the latter is called as a multi-driving method.

The control unit 30 receives sensing signals output from the plurality of receiving electrodes Rx0, Rx1, Rx2, Rx3 . . . Rx35, Rx36, and Rx37 of the touch sensor 10, and analog-to-digital converts the sensing signals output from the plurality of receiving electrodes Rx0, Rx1, Rx2, Rx3 . . . Rx35, Rx36, and Rx37 to output digital signals. Here, the output digital signal may be referred to as a capacitance variation or a “diff.”

The conventional electronic device may perform the proximity sensing by using the touch sensor 10. This will be described in detail with reference to FIGS. 3A and 3B.

FIGS. 3A and 3B are a view for explaining a proximity sensing method of the conventional electronic device in FIG. 2. Here, FIG. 3A is a view illustrating a method for applying predetermined driving signals to a plurality of driving electrodes during proximity sensing, and FIG. 3B is a view illustrating an example of a multi-driving code obtained by coding driving signals applied to the zeroth to seventh driving electrodes Tx0 to Tx7 during a first time interval in FIG. 3A.

Referring to FIGS. 2, 3A and 3B, in the conventional electronic device, the control unit 300 drives the plurality of driving electrodes Tx0, Tx1, Tx2, Tx3 . . . Tx16, Tx17, Tx18, and Tx19 in a multi-driving method for proximity sensing.

Specifically, as illustrated in FIG. 3A, predetermined driving signals are applied simultaneously to eight driving electrodes Tx0 to Tx7 among the plurality of driving electrodes Tx0, Tx1, Tx2, Tx3 . . . Tx16, Tx17, Tx18, and Tx19 during a first time interval, then predetermined driving signals are applied simultaneously to other eight driving electrodes Tx8 to Tx15 during a second time interval, and then predetermined driving signals are applied simultaneously to the remaining driving electrodes Tx16 to Tx19 during a third time interval.

As the predetermined driving signals are applied during respective time intervals, sensing signals are output from the plurality of receiving electrodes Rx0, Rx1, Rx2, Rx3 . . . Rx35, Rx36, and Rx37. The control unit 300, which receives the above-described sensing signals, calculates each of a first summed value obtained by summing capacitance variation values of sensing signals output from the receiving electrodes Rx0, Rx1, Rx2, Rx3, Rx4, . . . disposed at an upper portion TS of the touch sensor 100 and a second summed value obtained by summing capacitance variation values of sensing signals output from the receiving electrodes . . . Rx35, Rx36, Rx37, Rx38, Rx39 disposed at a lower portion BS of the touch sensor 100, and determines whether proximity sensing is to be performed based on a value obtained by subtracting the calculated second summed value from the calculated first summed value.

Since the proximity sensing method of the conventional electronic device subtracts the second summed value from the first summed value, display noise may be at least partially canceled.

However, the proximity sensing method of the conventional electronic device has a limitation of causing flicker in the display panel. Specifically, as illustrated in FIG. 3A, the maximum number of driving electrodes simultaneously driven during each time interval is eight. In this case, as illustrated in FIG. 3B, a sum of all codes of the driving signals applied simultaneously to eight driving electrodes Tx0 to Tx7 during an arbitrary time interval t1 to t4 is equal to ‘4’. When the sum of codes is equal to ‘4’, driving signals corresponding to four times of the driving signals are applied to the corresponding driving electrodes during the arbitrary time intervals t1 to t4. The high-voltage driving signals affect the display panel disposed adjacent to the touch sensor 100, thereby causing flicker in the display panel.

### DISCLOSURE OF THE INVENTION

### Technical Problem

The present invention provides an electronic device capable of improving or removing occurrence of flicker on a display screen during proximity sensing and a proximity sensing method thereof.

The present invention also provides an electronic device capable of enhancing a signal-to-noise ratio (SNR) and a proximity sensing method thereof.

The present invention also provides an electronic device capable of canceling a display noise and a proximity sensing method thereof.

### Technical Solution

An embodiment of the present invention provide an electronic device including: a sensor including a plurality of driving electrodes and a plurality of receiving electrodes arranged to intersect the plurality of driving electrodes; and a control unit configured to simultaneously drive the plurality of driving electrodes during a predetermined period of time for proximity sensing on a touch screen, and to detect whether an object is in proximity to the touch screen based on sensing signals from the plurality of receiving electrodes, in which the control unit is configured such that a positive (+) driving signal is applied to some driving electrodes of the plurality of driving electrodes, and a negative (−) driving signal is applied to remaining driving electrodes of the plurality of driving electrodes.

In an embodiment of the present invention, a proximity sensing method of a control unit of an electronic device including a sensor including a plurality of driving electrodes and a plurality of receiving electrodes arranged to intersect the plurality of driving electrodes and the control unit configured to control the sensor includes: controlling the plurality of driving electrodes to be driven simultaneously during a predetermined period of time for proximity sensing on the sensor such that a positive (+) driving signal is applied to some driving electrodes and a negative (−) driving signal is applied to the remaining driving electrodes among the plurality of driving electrodes; receiving sensing signals from the plurality of receiving electrodes; and detecting whether an object is in proximity to the sensor based on the sensing signals.

### Advantageous Effects

The electronic device according to the embodiment of the present invention and the proximity sensing method thereof may have an advantage of improving or removing the occurrence of the flicker in the display screen during the proximity sensing.

The electronic device may also have an advantage of enhancing the signal-to-noise ratio (SNR).

The electronic device may also have an advantage of canceling the display noise.

### BRIEF DESCRIPTION OF THE DRAWINGS

FIG. 1 is a schematic view illustrating a laminated structure of a typical OCTA method.

FIG. 2 is a view illustrating a proximity sensing method of a conventional electronic device.

FIG. 3A is a view illustrating a method for applying predetermined driving signals to a plurality of driving electrodes during proximity sensing, and FIG. 3B is a view illustrating an example of a multi-driving code obtained by coding driving signals applied to the zeroth to seventh driving electrodes Tx0 to Tx7 during a first time interval in FIG. 3A.

FIG. 4 is a schematic block diagram illustrating an electronic device according to an embodiment of the present invention.

FIG. 5A is a more detailed view illustrating a sensor 100 in FIG. 4, and FIG. 5B is a view for explaining a proximity sensing method of the sensor 100 in FIG. 5A.

FIG. 6 is a schematic block diagram illustrating an electronic device according to another embodiment of the present invention.

FIG. 7 is a plan view illustrating an embodiment of a touch sensor 100′ illustrated in FIG. 6.

FIG. 8 is a plan view illustrating a portion of another embodiment of the touch sensor 100′ in FIG. 6.

FIG. 9 is a plan view illustrating a portion of another embodiment of the touch sensor 100′ in FIG. 6.

FIG. 10 is a plan view illustrating a portion of another embodiment of the touch sensor 100′ in FIG. 6.

FIG. 11 is a schematic block diagram illustrating an electronic device according to another embodiment of the present invention.

FIG. 12 is a schematic block diagram illustrating an electronic device according to another embodiment of the present invention.

FIG. 13 is a schematic block diagram illustrating an electronic device according to another embodiment of the present invention.

FIG. 14 is a schematic block diagram illustrating an electronic device according to another embodiment of the present invention.

FIG. 15 is a schematic block diagram illustrating an electronic device according to another embodiment of the present invention.

FIG. 16 is a schematic block diagram illustrating an electronic device according to another embodiment of the present invention.

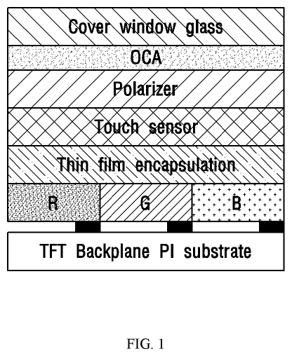

### MODE FOR CARRYING OUT THE INVENTION

The present invention will now be described more fully with reference to the accompanying drawings, in which exemplary embodiments of the invention are shown. These embodiments are provided so that this disclosure will be thorough and complete, and will fully convey the concept of the invention to those skilled in the art. The invention may, however, be embodied in many different forms and should not be construed as being limited to the embodiments set forth herein. Therefore, it will be understood that the embodiments disclosed in this specification includes some variations without limitations to the shapes as illustrated in the figures. Also, the position or the arrangement of each component in the embodiment may be varied without departing form the spirit or scope of the invention. The preferred embodiments should be considered in descriptive sense only and not for purposes of limitation. Therefore, the scope of the invention is defined not by the detailed description of the invention but by the appended claims, and all differences within the scope will be construed as being included in the present invention. In the drawings, like reference numerals refer to like elements throughout.

An electronic device according to various embodiments of the present document may include at least one of, e.g., a smartphone, a tablet personal computer (PC), a display device for a vehicle, a mobile phone, a video phone, an e-book reader, a laptop personal computer (laptop PC), a netbook computer, a mobile medical device, a camera, or a wearable device. Here, the wearable device may include at least one of an accessory device (e.g., a watch, a ring, a bracelet, an anklet, a necklace, glasses, contact lenses, or a head-mounted-device (HMD)), a fabric or integrated garment (e.g., electronic clothing), a body attachable (e.g., a skin pad or tattoo), and a bio-implantable device (e.g., an implantable circuit).

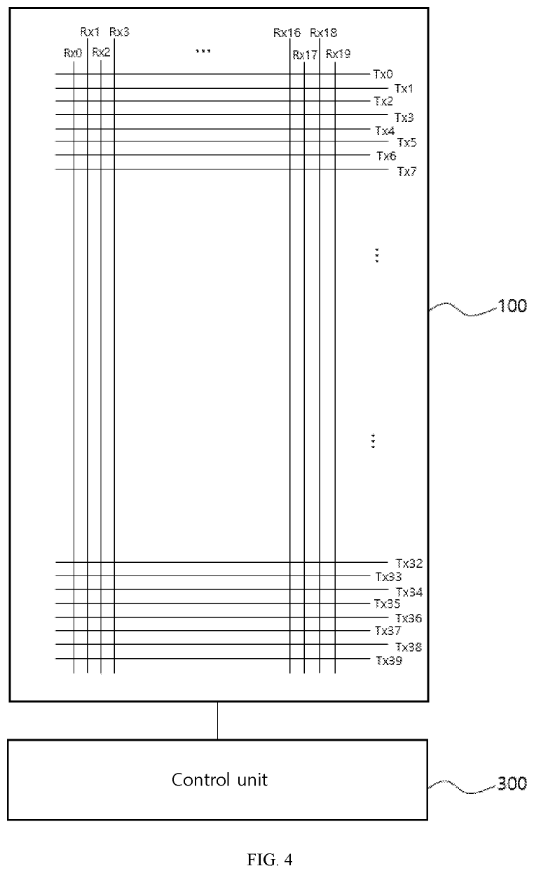

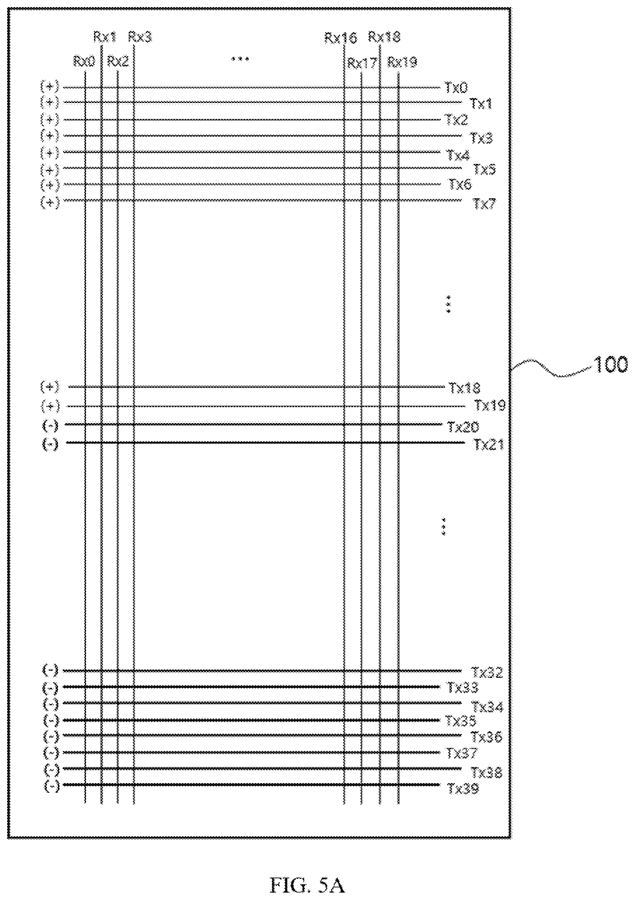

FIG. 4 is a schematic block diagram illustrating an electronic device according to an embodiment of the present invention.

Referring to FIG. 4, the electronic device according to an embodiment of the present invention includes a sensor 100 and a control unit 300.

The sensor 100 includes a plurality of driving electrodes Tx0, Tx1, Tx2, Tx3 . . . Tx36, Tx37, Tx38, and Tx39 and a plurality of receiving electrodes Rx0, Rx1, Rx2, Rx3 . . . Rx17, Rx18, and Rx19.

The plurality of driving electrodes Tx0, Tx1, Tx2, Tx3 . . . Tx36, Tx37, Tx38, and Tx39 are arranged to intersect the plurality of receiving electrodes Rx0, Rx1, Rx2, Rx3 . . . Rx17, Rx18, and Rx19.

A predetermined mutual capacitance Cm is formed between the plurality of driving electrodes Tx0, Tx1, Tx2, Tx3 . . . Tx36, Tx37, Tx38, and Tx39 and the plurality of receiving electrodes Rx0, Rx1, Rx2, Rx3 . . . Rx17, Rx18, and Rx19, particularly at intersections thereof.

Each of the receiving electrodes Rx0, Rx1, Rx2, Rx3 . . . Rx17, Rx18, Rx19, and Tx19 may be arranged in a first axial direction (or vertical direction), and each of the driving electrodes Tx1, Tx2, Tx3 . . . Tx36, Tx37, Tx38, and Tx39 is arranged in a second axial direction (or horizontal direction) different from the first axial direction. Here, the second axial direction may be perpendicular to the first axial direction. The first axial direction may be referred to as a major axis direction, and the second axial direction may be referred to as a minor axis direction.

According to an embodiment of the present invention, the electronic device has a display screen in which a longitudinal length is greater than a transverse length. For example, the electronic device may be a smartphone. Thus, each receiving electrode Rx0, Rx1, Rx2, Rx3 . . . Rx17, Rx18, and Rx19 disposed in the major axis direction is greater in length than each driving electrode Tx0, Tx1, Tx2, Tx3 . . . Tx36, Tx37, Tx38, and Tx39 disposed in the minor axis direction. Also, the number of the plurality of receiving electrodes Rx0, Rx1, Rx2, Rx3 . . . Rx17, Rx18, and Rx19 is less than that of the plurality of driving electrodes Tx0, Tx1, Tx2, Tx3 . . . Tx36, Tx37, Tx38, and Tx39.

The plurality of driving electrodes Tx0, Tx1, Tx2, . . . , Tx39 and the plurality of receiving electrodes Rx0, Rx1, Rx2, . . . Rx19 may be arranged together on the same layer (1 layer) or disposed respectively in different double layers (2 layers).

The plurality of driving electrodes Tx0, Tx1, Tx2, . . . , Tx39 and the plurality of receiving electrodes Rx0, Rx1, Rx2, . . . Rx19 may each have a diamond, circular, oval or polygonal shape.

The plurality of driving electrodes Tx0, Tx1, Tx2, . . . , Tx39 and the plurality of receiving electrodes Rx0, Rx1, Rx2, . . . Rx19 may be made of a metal mesh and patterned on a thin film encapsulation (TFE) layer of a display panel.

The electronic device according to an embodiment of the present invention in FIG. 4 may include a display panel (not shown) although not shown in FIG. 4. The sensor 100 may be disposed on a cell of the display panel as in an on-cell type or disposed in a cell of the display panel as in an in-cell type. Depending on cases, the sensor 100 may be disposed below the display panel.

For example, the sensor 100 may be directly formed on an outer surface (e.g., a top surface of an upper substrate or a bottom surface of a lower substrate) or an inner surface (e.g., a bottom surface of the upper substrate or a top surface of the lower substrate) of the upper substrate and/or the lower substrate of the display panel. The sensor 100 may be coupled to the display panel to constitute a touch screen panel TSP.

A plurality of scan lines (or gate lines) and a plurality of data lines may be disposed on the display panel. A subpixel may be disposed on an area in which the scan lines intersect the data lines. Each of the scan lines may be arranged in the same direction as the plurality of driving electrodes Tx0, Tx1, . . . , Tx38, and Tx39.

The display panel may include an active area on which a plurality of subpixels are disposed and an inactive area disposed outside the active area. The active area may constitute a display screen of the electronic device. The display screen may have a rectangular shape in which a vertical length is greater than a horizontal length.

The electronic device according to an embodiment in FIG. 4 may include a gate driving circuit, a data driving circuit, and a display control unit for driving various signal lines disposed on the display panel to drive the display panel.

The gate driving circuit may be controlled by the display control unit and control a driving timing of the plurality of subpixels by sequentially outputting display scan signals to the plurality of scan lines disposed on the display panel.

The data driving circuit may receive image data from the display control unit and convert the received image data into an analog type data voltage. The data driving circuit may control each subpixel to emit brightness based on the image data by outputting the data voltage (Vdata) to each data line in accordance with a timing when the scan signal is applied through the scan line.

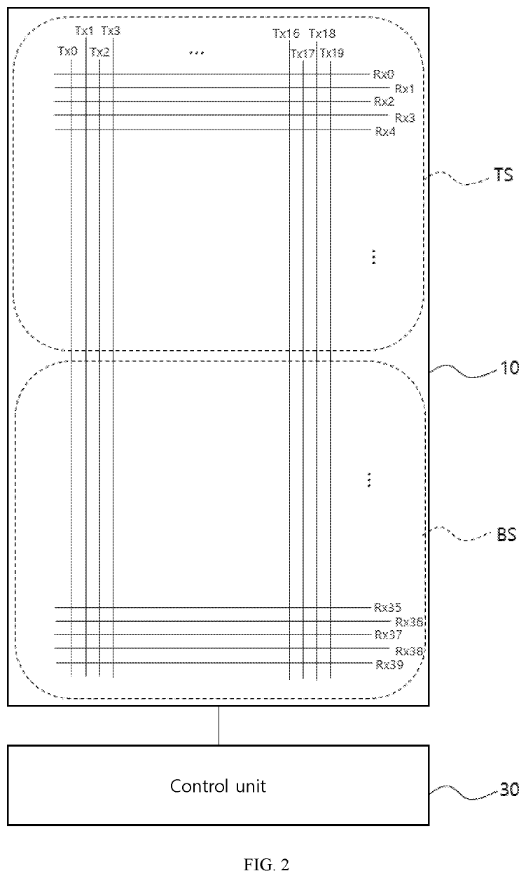

The display control unit may supply various control signals to the gate driving circuit and the data driving circuit and control operations of the gate driving circuit and the data driving circuit. The display control unit may be provided separately from or integrated with the control unit 300 in FIG. 2.

Referring to FIG. 4 again, the control unit 300 controls the sensor 100. Specifically, the control unit 300 applies a driving signal (or Tx signal) to each of the plurality of driving electrodes Tx0, Tx1, Tx2, Tx3 . . . Tx36, Tx37, Tx38, and Tx39 of the sensor 100, and receives a sensing signal (or Rx signal) from each of the plurality of receiving electrodes Rx0, Rx1, Rx2, Rx3 . . . Rx17, Rx18, and Rx19 of the sensor 100.

The control unit 300 receives the sensing signals output from the plurality of receiving electrodes Rx0, Rx1, Rx2, Rx3 . . . Rx17, Rx18, and Rx19 of the sensor 100, and analog-to-digital converts the sensing signals output from the plurality of receiving electrodes Rx0, Rx1, Rx2, Rx3 . . . Rx17, Rx18, and Rx19 into digital signals to output the converted digital signals. Here, the output digital signal may be referred to as a capacitance variation or a diff.

The control unit 300 may output two sensing signals among the sensing signals output from the plurality of receiving electrodes Rx0, Rx1, Rx2, Rx3 . . . Rx17, Rx18, and Rx19 as differential signals and analog-to-digital convert the output differential signals to output the converted digital signals. To this end, the control unit 300 may include a comparator and an ADC. The control unit 300 may detect whether a touch is generated and/or a touch position based on the output digital signal. Here, the output digital signal may be referred to as a capacitance variation or a diff.

The control unit 300 may be implemented as a single module, unit, or chip. However, the embodiment of the present invention is not limited thereto. For example, the control unit 300 may be divided into a sensing unit that receives a sensing signal from each of the receiving electrodes Rx0, Rx1, Rx2, Rx3 . . . Rx17, Rx18, and Rx19 of the sensor 100, a driving unit that applies a predetermined driving signal to the driving electrodes Tx0, Tx1, Tx2, Tx3 . . . Tx36, Tx37, Tx38, and Tx39 of the sensor 100, and a control unit that controls the sensing unit and the driving unit. Alternatively, at least two of the sensing unit, the driving unit, and the control unit may be implemented as a single module, unit, or chip.

The control unit 300 may sequentially apply driving signals to the plurality of driving electrodes Tx0, Tx1, Tx2, Tx3 . . . Tx36, Tx37, Tx38 and Tx39 of the sensor 100 or simultaneously apply predetermined driving signals to some driving electrodes of the plurality of driving electrodes Tx0, Tx1, Tx2, Tx3 . . . Tx36, Tx37, Tx38 and Tx39. The former is referred to as a sequential driving method, and the latter is referred to as a multi-driving method.

The control unit 300 may perform proximity sensing by using the sensor 100.

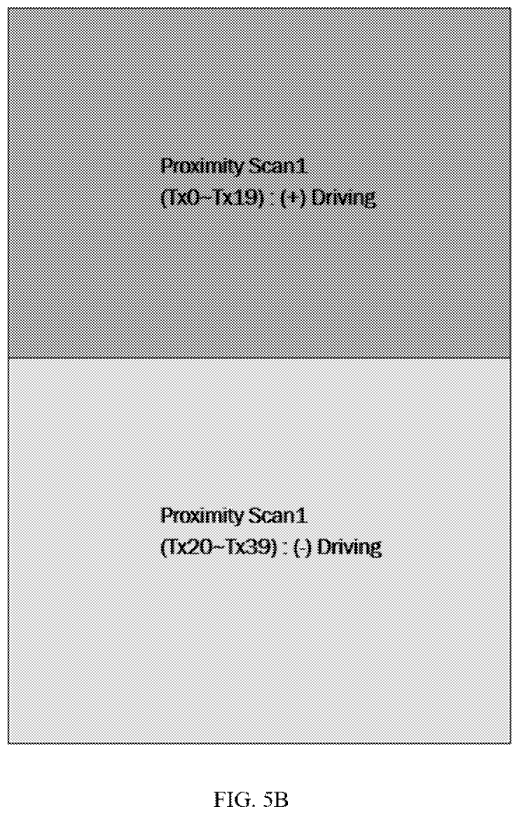

While the proximity sensing is performed, the control unit 300 may be configured to simultaneously apply predetermined driving signals to all of the plurality of driving electrodes Tx0, Tx1, Tx2, Tx3 . . . Tx36, Tx37, Tx38, and Tx39 of the sensor 100. This will be described with reference to FIGS. 5A and 5B.

FIGS. 5A and 5B are a view for explaining a proximity sensing method of the electronic device according to an embodiment of the present invention in FIG. 4. Here, FIG. 5A is a more detailed view illustrating the sensor 100 in FIG. 4, and FIG. 5B is a view for explaining the proximity sensing method of the sensor 100 in FIG. 5A.

Referring to FIGS. 4, 5A and 5B, the control unit 300 controls the plurality of driving electrodes Tx0, Tx1, Tx2, Tx3 . . . Tx36, Tx37, Tx38, and Tx39 to be driven simultaneously for a predetermined period of time to perform the proximity sensing (Proximity Scan 1). Here, positive (+) driving signals are applied to some driving electrodes Tx0, Tx1 . . . Tx18, and Tx19 of the plurality of driving electrodes Tx0, Tx1, Tx2, Tx3 . . . Tx36, Tx37, Tx38, and Tx39, and negative (−) driving signals are applied to the remaining driving electrodes Tx20, Tx21 . . . Tx38, and Tx39.

Here, the driving signals applied to the remaining driving electrodes Tx20, Tx21 . . . Tx38, and Tx39 may be generated by inverting, by 180°, the phases of the driving signals applied to the some driving electrodes Tx0, Tx1 . . . Tx18, and Tx19 by 180°.

As illustrated in FIG. 5B, a ratio between the number of the some driving electrodes Tx0, Tx1 . . . Tx18, and Tx19 and the number of the remaining driving electrodes Tx20, Tx21 . . . Tx38, and Tx39 may be equal to 1:1.

As described above, for the proximity sensing, while the control unit 300 controls the plurality of driving electrodes Tx0, Tx1, Tx2, Tx3 . . . Tx36, Tx37, Tx38, and Tx39 to be simultaneously driven during a predetermined period of time, when positive (+) driving signals are applied to the some driving electrodes Tx0, Tx1 . . . Tx18, Tx19 and negative (−) driving signals are applied to the remaining driving electrodes Tx20, Tx21 Tx38, Tx39, a sum of codes of the driving signals applied to all of the driving electrodes Tx0, Tx1, Tx2, Tx3 . . . Tx36, Tx37, Tx38, Tx39 during the predetermined period of time is equal to ‘0’.

For example, when driving signals corresponding to a digital code of ‘+1’ are applied to the some driving electrodes Tx0, Tx1 . . . Tx18, Tx19 during the predetermined period of time, and driving signals corresponding to a digital code of ‘−1’ are applied to the remaining driving electrodes Tx20, Tx21 . . . Tx38, Tx39, the sum of the codes of all driving signals simultaneously applied to all of the driving electrodes Tx0, Tx1, Tx2, Tx3 . . . Tx36, Tx37, Tx38, Tx39 during the predetermined period of time is equal to ‘0’.

As described above, when the sum of the codes of the driving signals applied to all of the driving electrodes Tx0, Tx1, Tx2, Tx3 . . . Tx36, Tx37, Tx38, Tx39 during the predetermined period of time is equal to ‘0’, since a total voltage magnitude of the driving signals applied to the sensor 100 during the predetermined period of time exhibits an effect of ‘0 V’, the driving signals do not cause a flicker problem in the display panel. Thus, occurrence of the flicker in the display screen may be prevented.

The some driving electrodes to which the positive (+) driving signals are applied among the plurality of driving electrodes arranged along the minor axis direction may be disposed at an upper portion of the display screen when the display screen is divided into upper and lower halves in the vertical direction. Also, the remaining driving electrodes to which the negative (−) driving signals are applied among the plurality of driving electrodes may be disposed at the lower portion of the display screen. Conversely, the negative (−) driving signals may be applied to the driving electrodes disposed at the upper portion of the display screen, and the positive (+) driving signals may be applied to the driving electrodes disposed at the lower portion of the display screen.

Also, the ratio between the number of the some driving electrodes Tx0, Tx1 . . . . Tx18, Tx19 and the number of the remaining driving electrodes Tx20, Tx21 . . . Tx38, Tx39 may be equal to 6:4 or 4:6. In this case, although the sum of the driving signals applied to all of the driving electrodes Tx0, Tx1, Tx2, Tx3 . . . Tx36, Tx37, Tx38, and Tx39 during the predetermined period of time is greater than 0, when the excess sum of the driving signals is equal to or less than 2, the user may not recognize the flicker even when the flicker occurs in the display screen, and the occurrence of the flicker may be easily relieved or removed by software.

As illustrated in FIG. 5B, when the driving signals are applied simultaneously to the plurality of driving electrodes Tx0, Tx1, Tx2, Tx3 . . . Tx36, Tx37, Tx38, and Tx39 during the predetermined period of time by the control unit 300, the sensing signals are output from the plurality of receiving electrodes Rx0, Rx1, Rx2, Rx3 . . . Rx17, Rx18, and Rx19.

Each of the sensing signals includes a summed value of variations of mutual capacitances between the respective receiving electrode (e.g., Rx0) that outputs the corresponding sensing signal and the plurality of driving electrodes Tx0, Tx1, Tx2, Tx3 . . . Tx36, Tx37, Tx38, and Tx39.

For example, the sensing signal output from the zeroth receiving electrode Rx0 includes information on a total capacitance variation that is a sum of a capacitance variation between the zeroth receiving electrode Rx0 and the zeroth driving electrode Tx0, a capacitance variation between the zeroth receiving electrode Rx0 and the first driving electrode Tx1, . . . , a capacitance variation between the zeroth receiving electrode Rx0 and the thirty-eighth driving electrode Tx38, and a capacitance variation between the zeroth receiving electrode Rx0 and the thirty-ninth driving electrode Tx39. Here, when the positive (+) driving signals are applied to the some driving electrodes Tx0, Tx1 . . . Tx18, and Tx19 and the negative (−) driving signals are applied to the remaining driving electrodes Tx20, Tx21 . . . Tx38, and Tx39, the total capacitance variation Ctotal may be expressed as shown in <Equation 1> below.

Cₜₒₜₐₗ=C0+ . . . +C19+(−C20)+ . . . +(−C39) [Equation 1]

In the above <Equation 1>, C0 denotes a capacitance variation between any one receiving electrode and the zeroth driving electrode Tx0, C1 denotes a capacitance variation between the receiving electrode and the first driving electrode Tx1, C19 denotes a capacitance variation between the receiving electrode and the nineteenth driving electrode Tx19, C20 denotes a capacitance variation between the receiving electrode and the twentieth driving electrode Tx20, and C39 denotes a capacitance variation between the receiving electrode and the thirty-ninth driving electrode Tx39.

In the above <Equation 1>, the capacitance variations from C20 to C39 have negative (−) values because the driving signals applied to the twentieth driving electrode Tx20 to the thirty-ninth driving electrode Tx39 are negative (−) driving signals.

Referring to FIG. 4 again, the control unit 300 may determine whether an object is in proximity based on the sensing signals output from the plurality of receiving electrodes Rx0, Rx1, Rx2, Rx3 . . . Rx17, Rx18, and Rx19.

Here, the control unit 300 may also sense whether the object is in proximity based on differential signals obtained by differentiating two sensing signals among the sensing signals output from the plurality of receiving electrodes Rx0, Rx1, Rx2, Rx3 Rx17, Rx18, and Rx19.

According to the proximity sensing method of the control unit 300 described above with reference to FIGS. 4 and 5, a signal-to-noise ratio (SNR) may be improved. In particular, the proximity sensing method of the electronic device according to an embodiment of the present invention may improve the SNR, by 11 dB, during proximity sensing by following two effects.

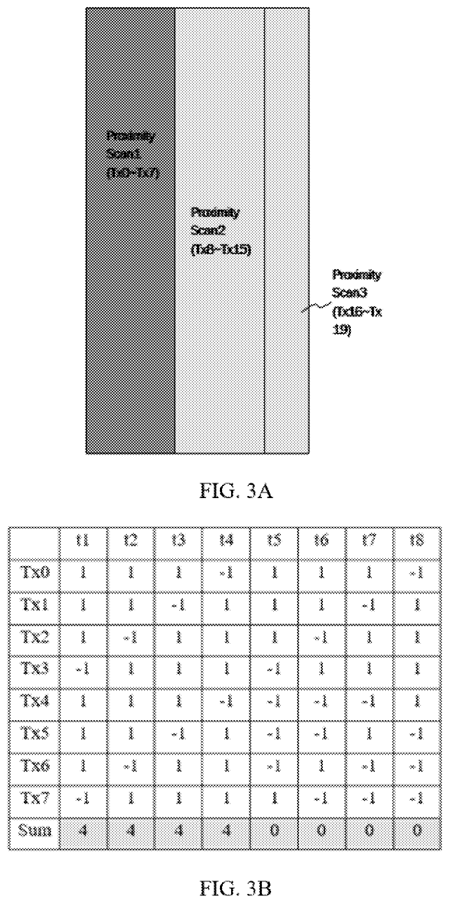

First, since the proximity sensing method of the electronic device according to an embodiment of the present invention simultaneously drives all of the driving electrodes during one period of time as illustrated in FIGS. 5A and 5B, an observation time of the proximity sensing increases by three times in comparison with the conventional driving method that requires at least three time intervals illustrated in FIG. 3A. Thus, the SNR may be improved by 5 dB.

Second, since the proximity sensing method of the electronic device according to an embodiment of the present invention simultaneously drives all of the driving electrodes during a predetermined period of time as illustrated in FIGS. 5A and 5B, the SNR may be further improved by 6 dB. A detailed description thereof will be provided with reference to Table 1 and Table 2 below.

TABLE 1

| | t0 | t1 | t2 | t3 |
|---|---|---|---|---|
| T × 0 | S0 | S0 | S0 | S0 |
| T × 1 | S1 | S1 | S1 | S1 |
| T × 2 | S2 | S2 | S2 | S2 |
| T × 3 | S3 | S3 | S3 | S3 |
| Signal | S0 + S1 + | S0 + S1 + | S0 + S1 + | S0 + S1 + |
| | S2 + S3 | S2 + S3 | S2 + S3 | S2 + S3 |
| Noise | n0 | n1 | n2 | n3 |

TABLE 2

| | t0 | t1 | t2 | t3 |
|---|---|---|---|---|
| T × 0 | S0 | S0 | S0 | −S0 |
| T × 1 | S1 | S1 | −S1 | S1 |
| T × 2 | S2 | −S2 | S2 | S2 |
| T × 3 | −S3 | S3 | S3 | S3 |
| Signal | S0 + S1 + | S0 + S1 − | S0 − S1 + | −S0 + S1 + |
| | S2 − S3 | S2 + S3 | S2 + S3 | S2 + S3 |
| Noise | n0 | n1 | n2 | n3 |

<Table 1> above is a table for explaining the SNR based on the proximity sensing method according to an embodiment of the present invention as illustrated in FIG. 5B, and <Table 2> above is a table for explaining the SNR based on the conventional proximity sensing method illustrated in FIG. 3A.

According to the above <Table 1>, in arbitrary time intervals t0 to t3, the SNR based on the proximity sensing method according to an embodiment of the present invention may be expressed as in <Equation 2> below. <Equation 2> below is obtained by summing all signals in the arbitrary time intervals t0 to t3.

SNR=4(S0+S1+S2+S3)/(n0+n1+x2+x3) [Equation 2]

On the other hand, according to the above <Table 2>, in the arbitrary time intervals t0 to t3, the SNR based on the conventional proximity sensing method may be expressed as in <Equation 3> below. <Equation 3> below is obtained by demodulating the signals in the arbitrary time intervals t0 to t3 such that, when a signal are demodulated into (1, 1, 1, −1) with respect to Tx0, the signal is equal to 4*S0, and the noise is equal to n0+n1+n2−n3.

SNR=4(S0+S1+S2+S3)/{(2(n0+n1+n2+n3)} [Equation 3]

When the <Equation 2> is compared with the <Equation 3>, it may be known that the SNR based on the proximity sensing method according to an embodiment of the present invention is twice (6 dB) greater than the SNR based on the conventional proximity sensing method.

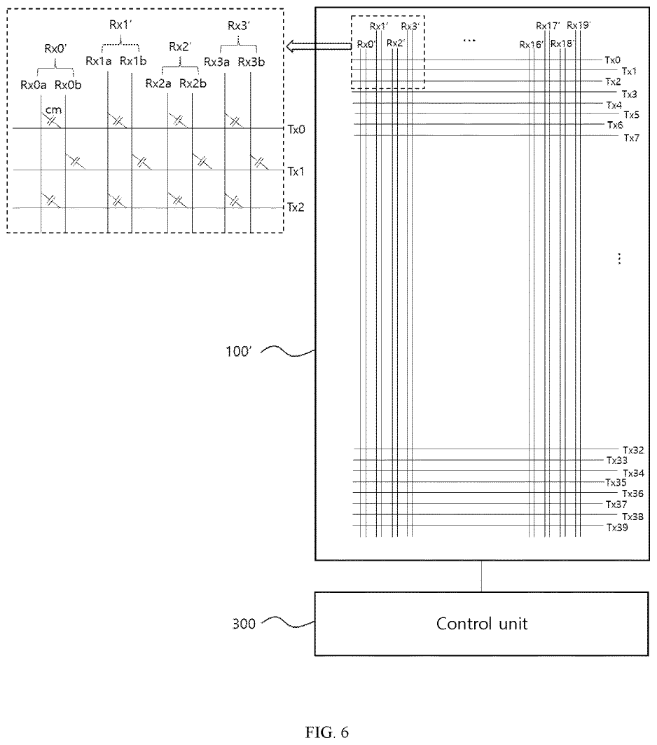

FIG. 6 is a schematic block diagram illustrating an electronic device according to another embodiment of the present invention.

The electronic input device according to another embodiment of the present invention illustrated in FIG. 6 is different in the sensor 100′ from the electronic device illustrated in FIG. 4.

Each of a plurality of receiving electrodes Rx0′, Rx1′, . . . , Rx18′, and Rx19′ of a sensor 100′ in FIG. 6 includes first receiving electrode units Rx0a, Rx1a, Rx2a, Rx3a, . . . and second receiving electrode units Rx0b, Rx1b, Rx2b, Rx3b . . . .

The first receiving electrode units Rx0a, Rx1a, Rx2a, Rx3a, . . . may be arranged to form a mutual capacitance cm with some driving electrodes Tx0, Tx2, Tx4, Tx6, . . . , Tx32, Tx34, Tx36, and Tx38 among a plurality of driving electrodes Tx0, Tx1, Tx2, . . . , Tx38, and Tx39 and to form little or no mutual capacitance cm with the remaining driving electrodes Tx1, Tx3, Tx5, Tx7, . . . , Tx33, Tx35, Tx37, and Tx39. Here, the forming of the little mutual capacitance cm may represent a relatively small mutual capacitance compared with the mutual capacitance cm with the some driving electrodes Tx0, Tx2, Tx4, Tx6, . . . , Tx32, Tx34, Tx36, and Tx38.

The second receiving electrode units Rx0b, Rx1b, Rx2b, Rx3b, . . . may be arranged to form a mutual capacitance cm with the remaining driving electrodes Tx1, Tx3, Tx5, Tx7, . . . , Tx33, Tx35, Tx37, and Tx39 among the plurality of driving electrodes Tx0, Tx1, Tx2, . . . , Tx38, and Tx39 and to form little or no mutual capacitance cm with the some driving electrodes Tx0, Tx2, Tx4, Tx6, . . . , Tx32, Tx34, Tx36, and Tx38. Here, the forming of the little mutual capacitance cm may represent a relatively small mutual capacitance compared with the mutual capacitance cm with the remaining driving electrodes Tx1, Tx3, Tx5, Tx7, . . . , Tx33, Tx35, Tx37, and Tx39.

The first receiving electrode units Rx0a, Rx1a, Rx2a, Rx3a, . . . may be arranged directly adjacent to the some driving electrodes Tx0, Tx2, Tx4, Tx6, . . . , Tx32, Tx34, Tx36, and Tx38 among the plurality of driving electrodes Tx0, Tx1, Tx2, . . . , Tx38, and Tx39 and be spaced a predetermined distance from the remaining driving electrodes Tx1, Tx3, Tx5, Tx7, . . . , Tx33, Tx35, Tx37, and Tx39 instead of being directly adjacent thereto. Here, at least one different electrode may be arranged between the first receiving electrode units Rx0a, Rx1a, Rx2a, Rx3a, . . . and the remaining driving electrodes Tx1, Tx3, Tx5, Tx7, . . . , Tx33, Tx35, Tx37, and Tx39. The different electrode may be at least one of the some driving electrodes Tx0, Tx2, Tx4, Tx6, . . . , Tx32, Tx34, Tx36, and Tx38.

The second receiving electrode units Rx0b, Rx1b, Rx2b, Rx3b, . . . may be arranged directly adjacent to the remaining driving electrodes Tx1, Tx3, Tx5, Tx7, . . . , Tx33, Tx35, Tx37, and Tx39 among the plurality of driving electrodes Tx0, Tx1, Tx2, . . . , Tx38, and Tx39 and be spaced a predetermined distance from the some driving electrodes Tx0, Tx2, Tx4, Tx6, . . . , Tx32, Tx34, Tx36, and Tx38 instead of being directly adjacent thereto. Here, at least one different electrode may be arranged between the second receiving electrode units Rx0b, Rx1b, Rx2b, Rx3b, . . . and the some driving electrodes Tx0, Tx2, Tx4, Tx6, . . . , Tx32, Tx34, Tx36, and Tx38. The different electrode may be at least one of the remaining driving electrodes Tx1, Tx3, Tx5, Tx7, . . . , Tx33, Tx35, Tx37, and Tx39.

An electronic device including the sensor 100′ and a control unit 300 in FIG. 6 may perform the proximity sensing.

While the proximity sensing is performed, when driving signals are applied during a predetermined period of time to all of the plurality of driving electrodes Tx0, Tx1, Tx2 . . . Tx38, and Tx39 by the controller 300 such that positive (+) driving signals are applied to upper driving electrodes Tx0 to Tx19 among the plurality of driving electrodes Tx0, Tx1, Tx2 . . . Tx38, and Tx39 and negative (−) driving signals are applied to lower driving electrodes Tx20 to Tx39, a first sensing signal is output from the first receiving electrode units Rx0a, Rx1a, Rx2a, Rx3a, . . . of each receiving electrode, and a second sensing signal is output from the second receiving electrode units Rx0b, Rx1b, Rx2b, Rx3b, . . . of each receiving electrode.

The control unit 300 may perform differential processing on the first sensing signal output from the first receiving electrode unit and the second sensing signal output from the second receiving electrode unit of each receiving electrode to output a differential signal, thereby detecting whether an object is in proximity based on the differential signals from all of the receiving electrodes.

Here, the first sensing signal includes information on mutual capacitance variations caused by an object, a display noise (e.g., Zebra noise), a variation caused by image change, a LGM noise in a floating state, and a noise caused by a cathode re-transmission phenomenon (as a magnitude of a resistance RELVSS of an ELVSS layer increases (i.e., as a GND decreases), a high-frequency signal is also transmitted to the receiving electrode of the sensor and added to a main signal). Also, although relatively little information on the mutual capacitance variations caused by the object exists in the second sensing signal, substantially same noise information included in the first sensing signal is included in the remaining noise information (the display noise (e.g., Zebra noise), the variation caused by image change, the LGM noise in the floating state, and the noise caused by the cathode re-transmission phenomenon). Thus, since the control unit 300 performs the differential processing on the first sensing signal and the second sensing signal, most of display noise signals in the differential signal may be removed.

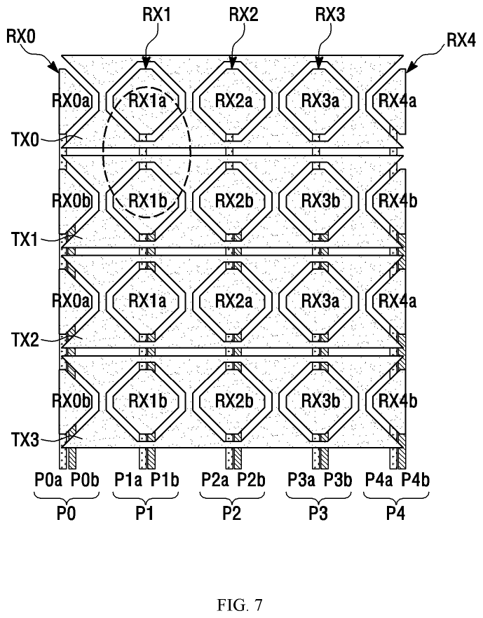

FIGS. 7 to 10 are views illustrating specific embodiments of the sensor 100′ illustrated in FIG. 6.

FIG. 7 is a plan view illustrating an embodiment of the sensor 100′ illustrated in FIG. 6.

Referring to FIG. 7, the sensor according to an embodiment of the present invention includes a plurality of first electrodes and a plurality of second electrodes. Among the plurality of first electrodes and the plurality of second electrodes, electrodes to which a driving signal is applied may serve as driving electrodes, and the remaining electrodes may serve as receiving electrodes. Hereinafter, the plurality of first electrodes serve as a plurality of driving electrodes TX0, TX1, TX2, TX3 . . . , and the plurality of second electrodes serve as a plurality of receiving electrodes RX0, RX1, RX2, RX3, RX4 . . . .

The plurality of driving electrodes TX0, TX1, TX2, TX3, . . . may include a zeroth driving electrode TX0, a first driving electrode TX1, a second driving electrode TX2, and a third driving electrode TX3. Here, the plurality of driving electrodes TX0, TX1, TX2, TX3 . . . correspond to the plurality of driving electrodes TX0, TX1, TX2, . . . illustrated in FIG. 6.

The plurality of receiving electrodes RX0, RX1, RX2, RX3, RX4, . . . may include a zeroth receiving electrode RX0, a first receiving electrode RX1, a second receiving electrode RX2, a third receiving electrode RX3, and a fourth receiving electrode RX4. Here, the plurality of receiving electrodes RX0, RX1, RX2, RX3, RX4, . . . correspond to the plurality of receiving electrodes RX0, RX1, Rx2, Rx4, . . . illustrated in FIG. 6.

The plurality of driving electrodes TX0, TX1, TX2, TX3, . . . are arranged in a second direction (or vertical direction) and each extend in a first direction (or horizontal direction) perpendicular to the second direction. The plurality of receiving electrodes RX0, RX1, RX2, RX3, RX4, . . . may be arranged in the second direction. Here, conversely, the plurality of driving electrodes TX0, TX1, TX2, TX3, . . . may be arranged in the first direction (or horizontal direction), and the plurality of receiving electrodes RX0, RX1, RX2, RX3, RX4, . . . may be arranged in the second direction (or vertical direction).

A predetermined capacitance may be formed between the plurality of driving electrodes TX0, TX1, TX2, TX3, . . . and the plurality of receiving electrodes RX0, RX1, RX2, RX3, RX4, . . . . The capacitance is varied when a touch input is generated at a corresponding point or a surrounding thereof. Thus, whether an object is in proximity, whether a touch is generated, and/or a touch input may be detected by detecting a capacitance variation from the signals output from the plurality of receiving electrodes Rx0, Rx1, Rx2, Rx3, Rx4, . . . .

Each of the plurality of driving electrodes TX0, TX1, TX2, TX3 . . . may have a rectangular pattern or bar pattern shape extending in the first direction and have, therein, a plurality of openings O arranged in the first direction.

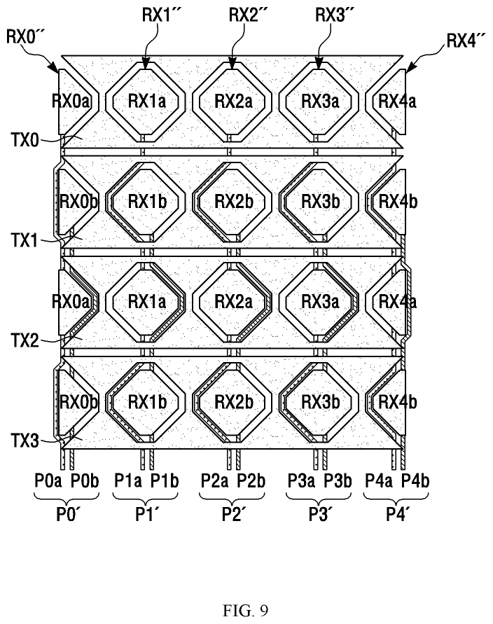

One receiving electrode may be disposed in each opening O. Each opening O has a shape corresponding to that of the one receiving electrode disposed therein. For example, as illustrated in FIG. 9, the remaining openings except for openings disposed on left and right edges among the plurality of openings O may each have a rhombus shape, and the openings disposed on the left and right edges may each have a triangular shape. Although not shown in the drawings, each of the openings O may have a rhombus shape. Also, each of the plurality of openings O may have various shapes such as a polygon, a rectangle, a circle or an oval.

Each of the receiving electrodes RX0, RX1, RX2, RX3, RX4, . . . includes a plurality of receiving electrode patterns RX0a, RX0b, RX1a, RX1b, RX2a, RX2b, RX3a, RX3b, RX4a, and RX4b and connecting patterns P0, P1, P2, P3, and P4. Here, some receiving electrode patterns RX0a, RX1a, RX2a, RX3a, and RX4a among the plurality of receiving electrode patterns RX0a, RX0b, RX1a, RX1b, RX2a, RX2b, RX3a, RX3b, RX4a, and RX4b may correspond to the first receiving electrode units Rx0a, Rx1a, Rx2a, Rx3a, . . . in FIG. 6, and the remaining receiving electrode patterns RX0b, RX1b, RX2b, RX3b, and RX4b may correspond to the second receiving electrode units Rx0b, Rx1b, Rx2b, Rx3b, . . . in FIG. 6.

The plurality of driving electrodes TX0, TX1, TX2, TX3, . . . and the plurality of receiving electrode patterns RX0a, RX0b, RX1a, RX1b, RX2a, RX2b, RX3a, RX3b, RX4a, and RX4b may be disposed together on a first layer. Here, the plurality of driving electrodes TX0, TX1, TX2, TX3 . . . and the plurality of receiving electrode patterns RX0a, RX0b, RX1a, RX1b, RX2a, RX2b, RX3a, RX3b, RX4a, and Rx4b, which are disposed on the first layer, may be implemented by using a metal mesh. The plurality of connecting patterns P0a, P0b, P1a, P1b, P2a, P2b, P3a, P3b, P4a, and P4b may be disposed on a second layer. The second layer is different from the first layer and electrically insulated from the first layer. Here, the plurality of connecting patterns P0a, P0b, P1a, P1b, P2a, P2b, P3a, P3b, P4a, and P4b may be implemented by using a metal mesh. The first layer may be disposed on the second layer, and vice versa.

The plurality of receiving electrode patterns included in each receiving electrode may be divided into at least two groups. The receiving electrode patterns of another group are alternately arranged between the receiving electrode patterns of one group. The receiving electrode patterns of the one group are electrically separated from the receiving electrode patterns of the another group. Here, the receiving electrode pattern in the one group may be referred to as a first receiving electrode pattern, and the receiving electrode pattern in the another group may be referred to as a second receiving electrode pattern.

The plurality of connection patterns included in each receiving electrode include first connection patterns that electrically connect the first receiving electrode patterns in the one group and second connection patterns that electrically connect the second receiving electrode patterns in the another group.

For example, the zeroth receiving electrode RX0 may include the plurality of receiving electrode patterns RX0a and RX0b and the plurality of connection patterns P0. The plurality of receiving electrode patterns RX0a and RX0b may include the receiving electrode patterns RX0a of a first group and the receiving electrode patterns Rx0b of a second group, which are alternately arranged one by one in the second direction. The receiving electrode patterns RX0a of the first group and the receiving electrode patterns RX0b of the second group may be electrically separated from each other. The zeroth connection pattern P0 may include first connection patterns P0a that electrically connect the receiving electrode patterns RX0a of the first group and second connection patterns P0b that electrically connect the receiving electrode patterns Rx0b of the second group.

The first receiving electrode RX1 may include the plurality of receiving electrode patterns RX1a and RX1b and the plurality of connection patterns P1. The plurality of receiving electrode patterns RX1a and RX1b may include the receiving electrode patterns RX1a of the first group and the receiving electrode patterns Rx1b of the second group, which are alternately arranged one by one in the second direction. The receiving electrode patterns RX1a of the first group and the receiving electrode patterns RX1b of the second group may be electrically separated from each other. The first connection pattern P1 may include first connection patterns P1a that electrically connect the receiving electrode patterns RX1a of the first group and second connection patterns P1b that electrically connect the receiving electrode patterns RX1b of the second group.

The second receiving electrode RX2 may include the plurality of receiving electrode patterns RX2a and RX2b and the plurality of connection patterns P2. The plurality of receiving electrode patterns RX2a and RX2b may include the receiving electrode patterns RX2a of the first group and the receiving electrode patterns Rx2b of the second group, which are alternately arranged one by one in the second direction. The receiving electrode patterns RX2a of the first group and the receiving electrode patterns RX2b of the second group may be electrically separated from each other. The second connection pattern P2 may include first connection patterns P2a that electrically connect the receiving electrode patterns RX2a of the first group and second connection patterns P2b that electrically connect the receiving electrode patterns RX2b of the second group.

The third receiving electrode RX3 may include the plurality of receiving electrode patterns RX3a and RX3b and the plurality of connection patterns P3. The plurality of receiving electrode patterns RX3a and RX3b may include the receiving electrode patterns RX3a of the first group and the receiving electrode patterns RX3b of the second group, which are alternately arranged one by one in the second direction. The receiving electrode patterns RX3a of the first group and the receiving electrode patterns RX3b of the second group may be electrically separated from each other. The third connection pattern P3 may include first connection patterns P3a that electrically connect the receiving electrode patterns RX3a of the first group and second connection patterns P3b that electrically connect the receiving electrode patterns Rx3b of the second group.

The fourth receiving electrode RX4 may include the plurality of receiving electrode patterns RX4a and RX4b and the plurality of connection patterns P4. The plurality of receiving electrode patterns RX4a and RX4b may include the receiving electrode patterns Rx4a of the first group and the receiving electrode patterns Rx4b of the second group, which are alternately arranged one by one in the second direction. The receiving electrode patterns RX4a of the first group and the receiving electrode patterns RX4b of the second group may be electrically separated from each other. The fourth connection pattern P4 may include first connection patterns P4a that electrically connect the receiving electrode patterns RX4a of the first group and second connection patterns P4b that electrically connect the receiving electrode patterns Rx4b of the second group.

The plurality of receiving electrode patterns RX0a, RX0b, RX1a, RX1b, RX2a, RX2b, RX3a, RX3b, RX4a, and RX4b are disposed in the plurality of openings O of the plurality of driving electrodes TX0, TX1, TX2, TX3 . . . . One receiving electrode pattern is disposed in one opening O. Each of the receiving electrode patterns has a shape corresponding to that of the corresponding opening.

In the arbitrary receiving electrode RX1, a portion of the driving electrode TX0 directly adjacent to a periphery of the receiving electrode pattern RX1a of the first group and a portion of the driving electrode TX1 directly adjacent to a periphery of the receiving electrode pattern RX1b of the second group are disposed together between the receiving electrode pattern RX1a of the first group and the receiving electrode pattern RX1b of the second group.

The arbitrary driving electrode TX0 is disposed directly adjacent to a periphery of the receiving electrode patterns RX0a, RX1a, RX2a, RX3a, and RX4a of one group, and another driving electrode TX1 disposed directly adjacent to a periphery of the receiving electrode patterns RX0a, RX1a, RX2a, RX3a, and RX4a of another group is separated from the receiving electrode patterns RX0a, RX1a, RX2a, RX3a, and RX4a of the one group by the arbitrary driving electrode TX0.

Each of the connection patterns P0a, P0b, P1a, P1b, P2a, P2b, P3a, P3b, P4a, and P4b may have a bar pattern shape extending in the second direction and include at least one conductive via v. The conductive via v may be disposed at both ends of each of the connection patterns.

In the zeroth receiving electrode RX0, each of the first connection patterns P0a electrically connects two adjacent receiving electrode patterns RX0a through the conductive via v among the receiving electrode patterns RX0a of the first group and is disposed below the receiving electrode patterns RX0b of the second group, which are disposed between the two adjacent receiving electrode patterns RX0a, to overlap the receiving electrode patterns RX0b of the second group. Each of the second connection patterns P0b electrically connects two adjacent receiving electrode patterns RX0b through the conductive via v among the receiving electrode patterns RX0b of the second group and is disposed below the receiving electrode patterns RX0a of the first group, which are disposed between the two adjacent receiving electrode patterns RX0b of the first group, to overlap the receiving electrode patterns RX0a of the first group. The first connection patterns P1a, P2a, P3a, and P4a and the second connection patterns P1b, P2b, P3b, and P4b of the remaining receiving electrodes RX1, RX2, RX3, and RX4 are disposed in the same manner as described above.

Hereinafter, an operation when predetermined driving signals are applied simultaneously to the plurality of driving electrodes TX0, TX1, TX2, and TX3 for proximity sensing will be described in detail.

When the driving signals are applied simultaneously to the plurality of driving electrodes TX0, TX1, TX2, and TX3, two sensing signals are output through the first connection pattern P1. A first sensing signal is output through the first connection pattern P1a, and a second sensing signal is output through the second connection pattern P1b. Thus, two channels of first and second sensing signals are output from each of the receiving electrodes RX0, RX1, RX2, RX3, and RX4. The first and second sensing signals are simultaneously output to the control unit 300 in FIG. 6.

The control unit 300 of FIG. 6 may perform differential processing on the first and second sensing signals to output the first and second sensing signals, thereby removing display noise signals or the like.

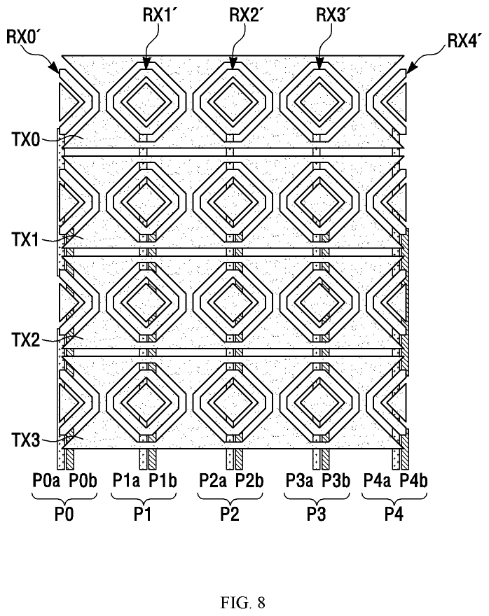

FIG. 8 is a plan view illustrating a portion of another embodiment of the sensor 100′ in FIG. 6.

The sensor according to another embodiment of the present invention in FIG. 8 is different in a plurality of receiving electrodes RX0′, RX1′, RX2′, RX3′, and RX4′ from the sensor according to an embodiment of the present invention in FIG. 7. In particular, a plurality of receiving electrode patterns RX1a′ included in each of the receiving electrodes RX0′, RX1′, RX2′, RX3′, and RX4′ have different structures. Hereinafter, the structures of the plurality of receiving electrode patterns RX1a′ will be described in detail, and the remaining components will be replaced with those described above.

Each of the plurality of receiving electrode patterns RX1a′ included in each of the receiving electrodes RX0′, RX1′, RX2′, RX3′, and RX4′ has an opening O′ therein and includes a dummy pattern DX1a disposed in the opening O′. Here, the dummy pattern DX1a may have a shape corresponding to the opening O′.

The dummy pattern DX1a is not electrically connected to connection patterns P0a, P0b, P1a, P1b, P2a, P2b, P3a, P3b, P4a, and P4b. The dummy pattern DX1a maintains an electrically floating state.

A proximity sensing operation of the sensor according to another embodiment of the present invention in FIG. 8 is the same as that of the sensor according to an embodiment of the present invention in FIG. 7. Thus, an electronic device including the sensor according to another embodiment of the present invention in FIG. 8 has an advantage of removing various noises generated during proximity sensing, e.g., the display noise and the LGM noise.

FIG. 9 is a plan view illustrating a portion of another embodiment of the sensor 100′ in FIG. 6.

The sensor according to another embodiment of the present invention in FIG. 9 is different in a plurality of receiving electrodes RX0″, RX1″, RX2″, RX3″, and RX4″ from the sensor according to an embodiment of the present invention in FIG. 7. In particular, a plurality of connection patterns P0′, P1′, P2′, P3′, and P4′ included in each of the receiving electrodes RX0″, RX1″, RX2″, RX3″, and RX4″ have different arrangement structures and shapes. Hereinafter, the arrangement structures and shapes of the connection patterns P0′, P1′, P2′, P3′, and P4′ will be described in detail, and the remaining components will be replaced with those described above.

Each of the connection patterns P0′, P1′, P2′, P3′, and P4′ includes first connection patterns P0a′, P1a′, P2a′, P3a′, and P4a′ and second connection patterns P0b′, P1b′, P2b′, P3b′, and P4b′.

Each of the first connection patterns P0a′, P1a′, P2a′, P3a′, and P4a′ electrically connects two receiving electrode patterns RX0a, RX1a, RX2a, RX3a, and RX4a of the first group so as not to overlap the receiving electrode patterns RX0b, RX1b, RX2b, RX3b, and RX4b of the second group disposed between the two receiving electrode patterns. For example, at least a portion of each of the first connection patterns P0a′, P1a′, P2a′, P3a′, and P4a′ may be disposed between the receiving electrode patterns RX0b, RX1b, RX2b, and Rx3b of the second group and the driving electrodes TX0, TX1, TX2, and TX3 disposed directly adjacent to the receiving electrode patterns RX0b, RX1b, RX2b, and RX3b of the second group so as not to overlap the receiving electrode patterns RX0b, RX1b, RX2b, RX3b, and Rx4b of the second group. Also, the rest portion may be disposed to overlap the driving electrodes TX0, TX1, TX2, and TX3.

Each of the second connection patterns P0b′, P1b′, P2b′, P3b′, and P4b′ electrically connects two receiving electrode patterns RX0a, RX1a, RX2a, RX3a, and RX4a of the second group so as not to overlap the receiving electrode patterns RX0a, RX1a, RX2a, RX3a, and RX4a of the first group disposed between the two receiving electrode patterns. For example, at least a portion of each of the second connection patterns P0b′, Pb′, P2b′, P3b′, and P4b′ may be disposed between the receiving electrode patterns RX0a, RX1a, RX2a, RX3a, and RX4a of the first group and the driving electrodes TX0, TX1, TX2, and TX3 disposed directly adjacent to the receiving electrode patterns RX0a, RX1a, RX2a, RX3a, and RX4a of the first group so as not to overlap the receiving electrode patterns RX0a, RX1a, RX2a, RX3a, and Rx4a of the first group. Also, the rest portion may be disposed to overlap the driving electrodes TX0, TX1, TX2, and TX3.

The sensor according to another embodiment of the present invention may have an advantage of reducing a value of capacitance between the first connection pattern and the receiving electrode patterns of the second group or between the second connection patterns and the receiving electrode patterns of the first group in comparison with the sensor according to an embodiment of the present invention in FIG. 7.

Although not shown in the drawings, the dummy pattern DX1a in FIG. 8 may be applied to the sensor according to another embodiment of the present invention.

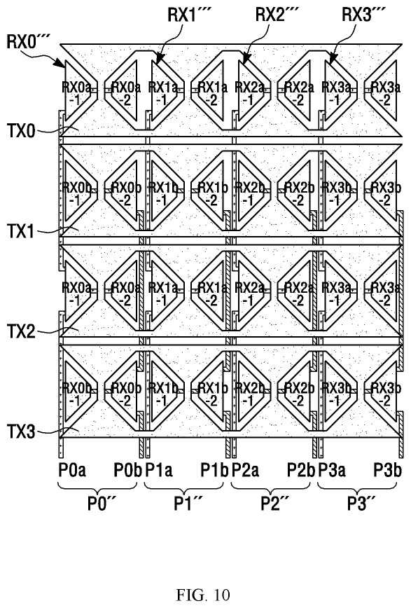

FIG. 10 is a plan view illustrating a portion of another embodiment of the sensor 100′ in FIG. 6.

The sensor according to another embodiment of the present invention in FIG. 10 is different in a plurality of receiving electrodes RX0″, RX1″, RX2″, and RX3″ from the sensor according to an embodiment of the present invention in FIG. 7. In particular, a plurality of receiving electrode patterns RX0a-1, RX0a-2, RX0b-1, RX0b-2, RX1a-1, RX1a-2, RX1b-1, RX1b-2, RX2a-1, RX2a-2, RX2b-1, RX2b-2, RX3a-1, RX3a-2, RX3b-1, and RX3b-2 and a plurality of connection patterns P0″, P1″, P2″, and P3″ included in each of the receiving electrodes RX0″, RX1″, RX2″, and RX3′″ have different structures and arrangement shapes. Hereinafter, the structures and arrangement shapes of the receiving electrode patterns RX0a-1, RX0a-2, RX0b-1, RX0b-2, RX1a-1, RX1a-2, RX1b-1, RX1b-2, RX2a-1, RX2a-2, RX2b-1, RX2b-2, RX3a-1, RX3a-2, RX3b-1, and RX3b-2 and the connection patterns P0″, P1″, P2″, and P3″ will be described in detail, and the remaining components will be replaced with those described above.

The plurality of receiving electrode patterns RX0a-1, RX0a-2, RX0b-1, RX0b-2, RX1a-1, RX1a-2, RX1b-1, RX1b-2, RX2a-1, RX2a-2, RX2b-1, RX2b-2, RX3a-1, RX3a-2, RX3b-1, and RX3b-2 of each of the receiving electrodes RX0″, RX1″, RX2″, and RX3″ include the receiving electrode patterns RX0a-1, RX0a-2, RX1a-1, RX1a-2, RX2a-1, RX2a-2, RX3a-1, and RX3a-2 of the first group and the receiving electrode patterns RX0b-1, RX0b-2, RX1b-1, RX1b-2, RX2b-1, RX2b-2, RX3b-1, and Rx3b-2 of the second group, which are alternately arranged one by one in the second direction. The receiving electrode patterns RX0a-1, RX0a-2, RX1a-1, RX1a-2, RX2a-1, RX2a-2, RX3a-1, and RX3a-2 of the first group and the receiving electrode patterns RX0b-1, RX0b-2, RX1b-1, RX1b-2, RX2b-1, RX2b-2, RX3b-1, and RX3b-2 of the second group may be electrically separated from each other. Each of the receiving electrode patterns RX0a-1, RX0a-2, RX1a-1, RX1a-2, RX2a-1, RX2a-2, RX3a-1, and RX3a-2 of the first group includes first receiving electrode patterns RX0a-1, RX1a-1, RX2a-1, and RX3a-1 and second receiving electrode patterns RX0a-2, RX1a-2, RX2a-2, and RX3a-2.

The first receiving electrode patterns RX0a-1, RX1a-1, RX2a-1, and RX3a-1 and the second receiving electrode patterns RX0a-2, RX1a-2, RX2a-2, and RX3a-2 are disposed in two openings O adjacent to each other in the first direction in the corresponding driving electrodes TX0 and TX2, respectively. One first or second receiving electrode pattern is disposed in the openings disposed at both side edges among a plurality of openings O of each of the driving electrodes TX0, TX1, TX2, and TX3, and the second receiving electrode pattern of the first group of receiving electrode patterns of one receiving electrode and the first receiving electrode pattern of the first group of receiving electrode patterns of another receiving electrode are disposed together in the remaining openings while being spaced apart from each other among the plurality of receiving electrodes RX0″′, RX1″′, RX2″′, and RX3″′.

Each of the connection patterns P0″, P1″, P2″, and P3″ includes first connection patterns P0a″, P1a″, P2a″, and P3a″ that electrically connect the receiving electrode patterns RX0a-1, RX0a-2, RX1a-1, RX1a-2, RX2a-1, RX2a-2, RX3a-1, and RX3a-2 of the first group and second connection patterns P0b″, P1b″, P2b″, and P3b″ that electrically connect the receiving electrode patterns RX0b-1, RX0b-2, RX1b-1, RX1b-2, RX2b-1, RX2b-2, RX3b-1, and Rx3b-2 of the second group.

Each of the first connection patterns P0a″, P1a″, P2a″, and P3a″ and the second connection patterns P0b″, P1b″, P2b″, and P3b″ are configured and arranged to connect two adjacent receiving electrode patterns for each group with a minimum distance. For example, each of the first connection patterns P0a″, P1a″, P2a″, and P3a″ and the second connection patterns P0b″, P1b″, P2b″, and P3b″ may have one end connected to one side of a lower end of one of two adjacent receiving electrode patterns of one group and the other end connected to one side of an upper end of the other receiving electrode pattern. The rest portion except for the one end and the other end has a shape extending in the second direction and overlaps the opening O of the driving electrode with a maximum cross-sectional area instead of overlapping the receiving electrode pattern of another group disposed between the one receiving electrode pattern and the other receiving electrode pattern.

Also, each of the first connection patterns P0a″, P1a″, P2a″, and P3a″ further includes a receiving connection pattern electrically connecting the first receiving electrode pattern and the second receiving electrode pattern of the first group of receiving electrode patterns, and each of the second connection patterns P0b″, P1b″, P2b″, and P3b″ further includes a receiving connection pattern electrically connecting the first receiving electrode pattern and the second receiving electrode pattern of the second group of receiving electrode patterns.

The sensor according to another embodiment of the present invention may have an advantage of reducing a value of resistance of each connection pattern and a value of capacitance between the first connection pattern and the receiving electrode pattern of the second group or between the second connection pattern and the receiving electrode pattern of the first group in comparison with the sensor according to an embodiment of the present invention in FIG. 7.

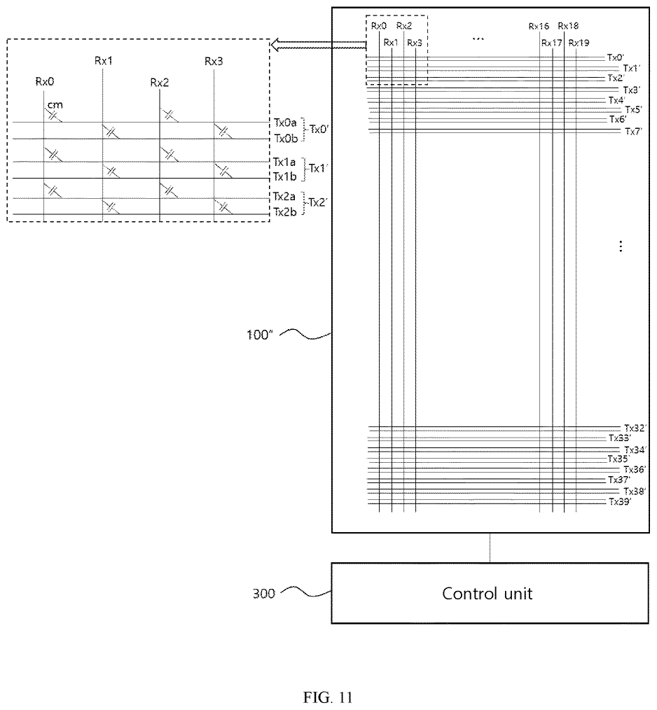

FIG. 11 is a schematic block diagram illustrating an electronic according to another embodiment of the present invention.

The electronic device according to another embodiment of the present invention in FIG. 11 is different in a sensor 100″ from the electronic device illustrated in FIG. 4.

The sensor 100″ illustrated in FIG. 11 is different in a plurality of driving electrodes Tx0′, Tx1′, . . . , Tx38′, and Tx39′ from the sensor 100 illustrated in FIG. 4. Specifically, each of the plurality of driving electrodes Tx0′, Tx1′, . . . , Tx38′, and Tx39′ includes first driving electrode units Tx0a, Tx1a, Tx2a, Tx3a, . . . and second driving electrode units Tx0b, Tx1b, Tx2b, Tx3b . . . .

The first driving electrode units Tx0a, Tx1a, Tx2a, Tx3a, . . . may form the mutual capacitance cm with some receiving electrodes Rx0, Rx2, . . . , Rx16, and Rx18 of the plurality of receiving electrodes Rx0, Rx1, Rx2, . . . , Rx18, and Rx19 and may form little or no mutual capacitance cm with remaining receiving electrodes Rx1, Rx3, . . . , Rx17, and Rx19. Here, the forming of the little mutual capacitance cm may represent a relatively small mutual capacitance value compared with the mutual capacitance cm with the some receiving electrodes Rx0, Rx2, . . . , Rx16, and Rx18.

The second driving electrode units Tx0b, Tx1b, Tx2b, Tx3b, . . . may form the mutual capacitance cm with the remaining receiving electrodes Rx1, Rx3, . . . , Rx17, and Rx19 of the plurality of receiving electrodes Rx0, Rx1, Rx2, . . . , Rx18, and Rx19 and may form little or no mutual capacitance cm with the some receiving electrodes Rx0, Rx2, . . . , Rx16, and Rx18. Here, the forming of the little mutual capacitance cm may represent a relatively small mutual capacitance value compared with the mutual capacitance cm with the remaining receiving electrodes Rx1, Rx3, . . . , Rx17, and Rx19.

The first driving electrode units Tx0a, Tx1a, Tx2a, Tx3a, . . . may be disposed directly adjacent to the some receiving electrodes Rx0, Rx2, . . . , Rx16, and Rx18 of the plurality of receiving electrodes Rx0, Rx1, Rx2, . . . , Rx18, and Rx19 and spaced a predetermined distance from the remaining receiving electrodes Rx1, Rx3, . . . , Rx17, and Rx19 instead of being directly adjacent thereto. Here, at least one different electrode may be disposed between the first driving electrode units Tx0a, Tx1a, Tx2a, Tx3a, . . . and the remaining receiving electrodes Rx1, Rx3, . . . , Rx17, and Rx19. The different electrode may be at least one of the some receiving electrodes Rx0, Rx2, . . . , Rx16, and Rx18.

The second driving electrode units Tx0b, Tx1b, Tx2b, Tx3b, . . . may be disposed directly adjacent to the remaining receiving electrodes Rx1, Rx3, . . . , Rx17, and Rx19 of the plurality of receiving electrodes Rx0, Rx1, Rx2, . . . , Rx18, and Rx19 and spaced a predetermined distance from the sine receiving electrodes Rx0, Rx2, . . . , Rx16, and Rx18 instead of being directly adjacent thereto. Here, at least one different electrode may be disposed between the second driving electrode units Tx0b, Tx1b, Tx2b, Tx3b, . . . and the some receiving electrodes Rx0, Rx2, . . . , Rx16, and Rx18. The different electrode may be at least one of the remaining receiving electrodes Rx1, Rx3, . . . , Rx17, and Rx19.

In each of the driving electrode Tx0′, Tx1′, . . . , Tx38′, and Tx39′, the second driving signal applied to the second driving electrode Tx0b, Tx1b, Tx2b, Tx3b, . . . is obtained by shifting the first driving signal applied to the first driving electrodes Tx0a, Tx1a, Tx2a, Tx3a, . . . by 180°.

An electronic device including the sensor 100″ and the control unit 300 illustrated in FIG. 11 may also perform the proximity sensing.

While the proximity sensing is performed, when driving signals are applied during a predetermined period of time to all of the plurality of driving electrodes Tx0′, Tx1′, Tx2′, . . . , Tx38′, Tx39′ by the controller 300 such that positive (+) driving signals are applied to upper driving electrodes Tx0′ to Tx19′ among the plurality of driving electrodes Tx0′, Tx1′, Tx2′, . . . Tx38′, and Tx39′ and negative (−) driving signals are applied to lower driving electrodes Tx20′ to Tx39′, a sensing signal is output from each of the receiving electrodes Rx0, Rx1, Rx2, Rx3, . . . The control unit 300 may detect whether an object is in proximity based on the output sensing signals.

Here, since information on mutual capacitance variations caused by an object, a display noise (e.g., Zebra noise), a variation caused by image change, a LGM noise in a floating state, and a noise caused by a cathode re-transmission phenomenon (as a magnitude of a resistance RELVSS of an ELVSS layer increases (i.e., as a GND decreases), a high-frequency signal is also transmitted to the receiving electrode of the sensor and added to a main signal) are canceled in the output sensing signal, the display noise and the like may be removed.

Embodiments of the sensor 100″′ illustrated in FIG. 11 may be implemented by replacing the receiving electrodes RX0, RX1, RX2, RX3, and RX4 with the driving electrodes TX0, TX1, TX2, TX3, and TX4, and, conversely, replacing the driving electrodes TX0, TX1, TX2, TX3, and TX4 with the receiving electrodes RX0, RX1, RX2, RX3, and RX4 in the sensors illustrated in FIGS. 7 to 10.

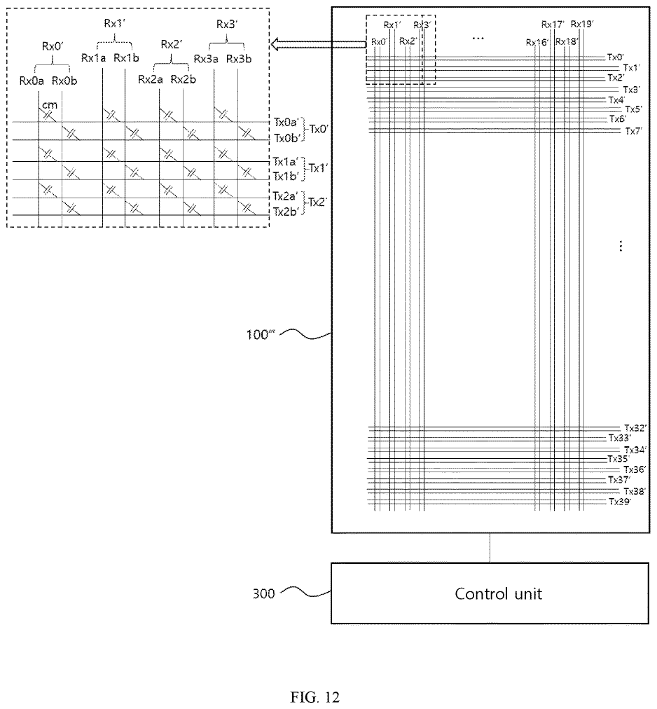

FIG. 12 is a schematic block diagram illustrating an electronic device according to another embodiment of the present invention.

The electronic device according to another embodiment of the present invention in FIG. 12 is different in a sensor 100″′ from the electronic device in FIG. 4.

The sensor 100′″ illustrated in FIG. 12 includes the plurality of receiving electrodes Rx0′, Rx1′, Rx2′, . . . , Rx18′, and Rx19′ illustrated in FIG. 6 and the plurality of driving electrodes Tx0′, Tx1′, Tx2′, . . . , Tx38′, and Tx39′ illustrated in FIG. 11.

The electronic device including sensor 100″′ may also perform the proximity sensing. While the proximity sensing is performed, the electronic device may drive simultaneously all of the plurality of driving electrodes Tx0′, Tx1′, Tx2′, . . . , Tx38′, Tx39′ for a predetermined period of time and detect whether an object is in proximity based on sensing signals output from the respective receiving electrodes Rx0′, Rx1′, Rx2′ . . . , Rx18′, Rx19′.

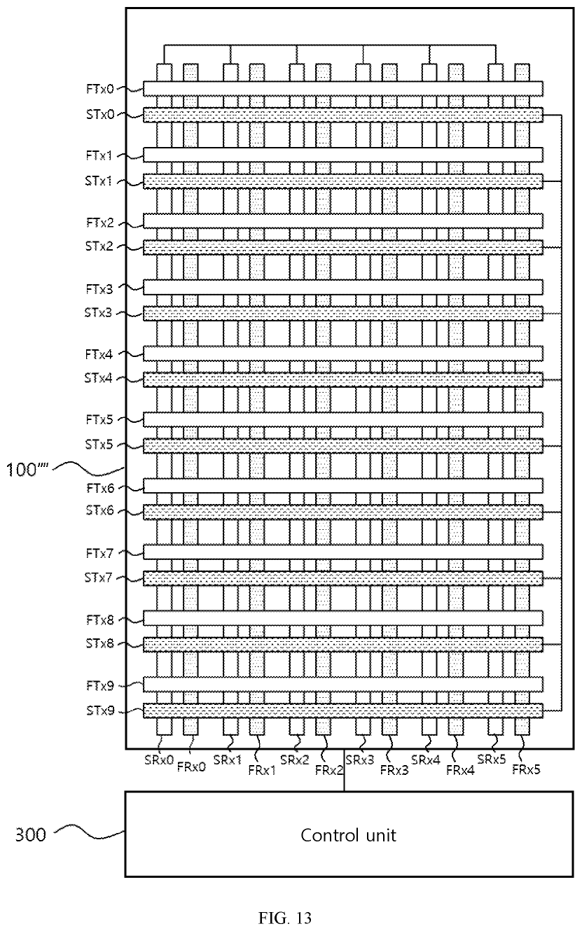

FIG. 13 is a schematic block diagram illustrating an electronic according to another embodiment of the present invention.

The electronic device according to another embodiment of the present invention in FIG. 13 is different in a sensor 100″″ from the electronic device in FIG. 4.

The electronic device including the sensor 100″″ and the control unit 300 may detect a position of an object such as a finger disposed on a screen, output a driving signal for driving a stylus pen, or detect a pen signal emitted from the stylus pen so as to detect the position of the stylus pen that is in proximity to or in contact with the display screen.

The sensor 100″″ includes a plurality of touch driving electrodes FTx0, FTx1, . . . , FTx8, and FTx9, a plurality of pen driving electrodes STx0, STx1, . . . , STx8, and STx9, a plurality of touch receiving electrodes FRx0, FRx1, . . . , FRx4, and FRx5, and a plurality of pen receiving electrodes SRx0, SRx1, . . . , SRx4, and SRx5.

Each of the touch driving electrodes FTx0, FTx1, . . . , FTx8, and FTx9 is arranged in the same direction as a scan line of a display panel (not shown). Here, the same direction as the scan line may be a minor axis direction of the electronic device. Each of the touch driving electrodes FTx0, FTx1, . . . , FTx8, and Ftx9 receives a touch driving signal for sensing an object such as a finger or a conductive member.

Each of the pen driving electrodes STx0, STx1, . . . , STx8, and STx9 is disposed adjacent to the touch driving electrodes FTx0, FTx1, . . . , FTx8, and FTx9 and spaced a predetermined distance from the touch driving electrodes FTx0, FTx1, . . . , FTx8, and FTx9. Each of the touch driving electrodes STx0, STx1, . . . , STx8, and STx9 is arranged in the same direction as the scan line of the display panel (not shown). Each of the pen driving electrodes STx0, STx1, . . . , STx8, and Stx9 may receive the pen driving signal for driving the stylus pen or detect a pen signal from the stylus pen.

One ends of the pen driving electrodes STx0, STx1, . . . , STx8, and STx9 may be electrically connected to each other through a conductive pattern. Here, the conductive pattern may be a metal mesh or a silver trace.

Each of the touch receiving electrodes FRx0, FRx1, . . . , FRx4, and FRx5 is arranged in a direction different from the direction in which each of the touch driving electrodes FTx0, FTx1, . . . , FTx8, and FTx9 is arranged. Each of the touch driving electrodes FRx0, FRx1, . . . , FRx4, and FRx5 outputs a touch sensing signal for sensing an object such as a finger or a conductive member.

Each of the pen receiving electrodes SRx0, SRx1, . . . , SRx4, and SRx5 is disposed adjacent to the touch receiving electrodes FRx0, FRx1, . . . , FRx4, and FRx5 and spaced a predetermined distance from the touch receiving electrodes FRx0, FRx1, . . . , FRx4, and FRx5. Each of the pen receiving electrodes SRx0, SRx1, . . . , SRx4, and SRx5 is arranged in a direction different from the direction in which each of the pen driving electrodes STx0, STx1, . . . , STx8, and STx9 is arranged. Each of the pen receiving electrodes SRx0, SRx1, . . . , SRx4, and SRx5 may receive the pen driving signal for driving the stylus pen or detect the pen signal from the stylus pen.

One ends of the pen receiving electrodes SRx0, SRx1, . . . , SRx4, and Stx5 may be electrically connected to each other through a conductive pattern. Here, the conductive pattern may be a metal mesh or a silver trace.

The plurality of touch receiving electrodes FRx0, FRx1, . . . , FRx4, and FRx5 and the plurality of pen receiving electrodes SRx0, SRx1, . . . , SRx4, and SRx5 may be disposed on the plurality of touch driving electrodes FTx0, FTx1, . . . , FTx8, and FTx9 and the plurality of pen driving electrodes STx0, STx1, . . . , STx8, and STx9 and spaced a predetermined distance from the plurality of touch driving electrodes FTx0, FTx1, . . . , FTx8, and FTx9 and the plurality of pen driving electrodes STx0, STx1, . . . , STx8, and STx9.

The number of the plurality of touch driving electrodes FTx0, FTx1, . . . , FTx8, and FTx9 and the number of the plurality of touch receiving electrodes FRx0, FRx1, . . . , FRx4, and FRx5 may increase or decrease depending on relative lengths of the major axis and the minor axis or a size of the screen of the electronic device.

The plurality of touch driving electrodes FTx0, FTx1, . . . , FTx8, and FTx9 and the plurality of touch receiving electrodes FRx0, FRx1, . . . , FRx4, and FRx5 basically sense the touch of the object such as a finger and a conductive member. To this end, the plurality of touch driving electrodes FTx0, FTx1, . . . , FTx8, and FTx9 may operate as the touch driving electrode to which the touch driving signal is applied, and the plurality of touch receiving electrodes FRx0, FRx1, . . . , FRx4, and FRx5 may operate as the touch sensing electrode (or touch receiving electrode) that receives the touch sensing signal. Alternatively, the operation may be performed in reverse

The sensor 100″″ of the electronic device in FIG. 13 may drive and sense the stylus pen by using various combinations of the plurality of touch driving electrodes FTx0, FTx1, . . . , FTx8, and FTx9, the plurality of pen driving electrodes STx0, STx1, . . . , STx8, and STx9, the plurality of touch receiving electrodes FRx0, FRx1, . . . , FRx4, and FRx5, and the plurality of pen receiving electrodes SRx0, SRx1, . . . , SRx4, and SRx5. The various combinations are shown in <Table 3> below. In the <Table 3> below, ‘1’ denotes the plurality of touch driving electrodes FTx0, FTx1, . . . , FTx8, and FTx9, ‘2’ denotes the plurality of pen driving electrodes STx0, STx1, . . . , STx8, and STx9, ‘3’ denotes the plurality of touch receiving electrodes FRx0, FRx1, . . . , FRx4, and FRx5, and ‘4’ denotes the plurality of pen receiving electrodes SRx0, SRx1, . . . , SRx4, and SRx5.

TABLE 3

| | | | Stylus | | | | | | | | | |
|---|---|---|---|---|---|---|---|---|---|---|---|---|
| | Finger Touch | | Operation | | | | Uplink signal | | Downlink signal | | | |
| | Operation | | Driving | | Sensing | | magnitude | | magnitude | | Stylus additional | |
| | Driving | Sensing | Major | Minor | X- | Y- | Major | Minor | X- | Y- | channel | |
| No. | Tx | Rx | axis | axis | axis | axis | axis | axis | axis | axis | Driving | Sensing |
| 1 | 1 | 3 | 2 | | 1 | 3 | Large | | Small | Small | Yes | No |
| 2 | 1 | 3 | 2 | | 1 | 4 | Large | | Small | Large | Yes | Yes |
| 3 | 1 | 3 | 2 | | 2 | 3 | Large | | Large | Small | Yes | Yes |
| 4 | 1 | 3 | 2 | | 2 | 4 | Large | | Large | Large | Yes | Yes |
| 5 | 1 | 3 | | 4 | 1 | 3 | | Large | Small | Small | Yes | No |
| 6 | 1 | 3 | | 4 | 1 | 4 | | Large | Small | Large | Yes | Yes |
| 7 | 1 | 3 | | 4 | 2 | 3 | | Large | Large | Small | Yes | Yes |
| 8 | 1 | 3 | | 4 | 2 | 4 | | Large | Large | Large | Yes | Yes |
| 9 | 1 | 3 | 2 | 4 | 1 | 3 | Large | Large | Small | Small | Yes | No |
| 10 | 1 | 3 | 2 | 4 | 1 | 4 | Large | Large | Small | Large | Yes | Yes |
| 11 | 1 | 3 | 2 | 4 | 2 | 3 | Large | Large | Large | Small | Yes | Yes |
| 12 | 1 | 3 | 2 | 4 | 2 | 4 | Large | Large | Large | Large | Yes | Yes |
| 13 | 1 | 3 | 1 | | 1 | 3 | Small | | Small | Small | No | No |
| 14 | 1 | 3 | 1 | | 1 | 4 | Small | | Small | Large | No | Yes |
| 15 | 1 | 3 | 1 | | 2 | 3 | Small | | Large | Small | No | Yes |
| 16 | 1 | 3 | 1 | | 2 | 4 | Small | | Large | Large | No | Yes |
| 17 | 1 | 3 | | 3 | 1 | 3 | | Small | Small | Small | No | No |
| 18 | 1 | 3 | | 3 | 1 | 4 | | Small | Small | Large | No | Yes |
| 19 | 1 | 3 | | 3 | 2 | 3 | | Small | Large | Small | No | Yes |
| 20 | 1 | 3 | | 3 | 2 | 4 | | Small | Large | Large | No | Yes |
| 21 | 1 | 3 | 1 | 3 | 1 | 3 | Small | Small | Small | Small | No | No |
| 22 | 1 | 3 | 1 | 3 | 1 | 4 | Small | Small | Small | Large | No | Yes |
| 23 | 1 | 3 | 1 | 3 | 2 | 3 | Small | Small | Large | Small | No | Yes |
| 24 | 1 | 3 | 1 | 3 | 2 | 4 | Small | Small | Large | Large | No | Yes |
| 25 | 1 | 3 | 2 | 3 | 1 | 3 | Large | Small | Small | Small | Yes | No |
| 26 | 1 | 3 | 2 | 3 | 1 | 4 | Large | Small | Small | Large | Yes | Yes |
| 27 | 1 | 3 | 2 | 3 | 2 | 3 | Large | Small | Large | Small | Yes | Yes |
| 28 | 1 | 3 | 2 | 3 | 2 | 4 | Large | Small | Large | Large | Yes | Yes |
| 29 | 1 | 3 | 1 | 4 | 1 | 3 | Small | Large | Small | Small | Yes | No |
| 30 | 1 | 3 | 1 | 4 | 1 | 4 | Small | Large | Small | Large | Yes | Yes |
| 31 | 1 | 3 | 1 | 4 | 2 | 3 | Small | Large | Large | Small | Yes | Yes |
| 32 | 1 | 3 | 1 | 4 | 2 | 4 | Small | Large | Large | Large | Yes | Yes |

Referring to <Table 3> above, in various combinations No. 1 to No. 32, the plurality of touch driving electrodes FTx0, FTx1, . . . , FTx8, and FTx9 and the plurality of touch receiving electrodes FRx0, FRx1, . . . , FRx4, and FRx5 sense the touch of the object such as a finger.

One or two of the plurality of touch driving electrodes FTx0, FTx1, . . . , FTx8, and FTx9, the plurality of pen driving electrodes STx0, STx1, . . . , STx8, and STx9, the plurality of touch receiving electrodes FRx0, FRx1, . . . , FRx4, and FRx5, and the plurality of pen receiving electrodes SRx0, SRx1, . . . , SRx4, and SRx5 may operate as a stylus driving electrode for driving the stylus pen. A current loop for driving the stylus pen may be formed by using a pattern of one or two of the plurality of touch driving electrodes FTx0, FTx1, . . . , FTx8, and FTx9, the plurality of pen driving electrodes STx0, STx1, . . . , STx8, and STx9, the plurality of touch receiving electrodes FRx0, FRx1, . . . , FRx4, and FRx5, and the plurality of pen receiving electrodes SRx0, SRx1, . . . , SRx4, and SRx5. An X-axis driving may be performed by one kind of electrodes of the plurality of touch driving electrodes FTx0, FTx1, . . . , FTx8, and FTx9 and the plurality of pen driving electrodes STx0, STx1, . . . , STx8, and Stx9, and a Y-axis driving may be performed by one kind of electrodes of the plurality of touch receiving electrodes FRx0, FRx1, . . . , FRx4, and FRx5 and the plurality of pen receiving electrodes SRx0, SRx1, . . . , SRx4, and SRx5. The driving of the stylus pen may be performed by either the X-axis driving or the Y-axis driving or by both the X-axis driving and the Y-axis driving.

Two of the plurality of touch driving electrodes FTx0, FTx1, . . . , FTx8, and FTx9, the plurality of pen driving electrodes STx0, STx1, . . . , STx8, and STx9, the plurality of touch receiving electrodes FRx0, FRx1, . . . , FRx4, and FRx5, and the plurality of pen receiving electrodes SRx0, SRx1, . . . , SRx4, and SRx5 may operate as sensing electrodes for sensing the stylus pen. Since all of X-axis sensing and Y-axis sensing are required to sense the stylus pen signal, two patterns are used among the plurality of touch driving electrodes FTx0, FTx1, . . . , FTx8, and FTx9, the plurality of pen driving electrodes STx0, STx1, . . . , STx8, and STx9, the plurality of touch receiving electrodes FRx0, FRx1, . . . , FRx4, and FRx5, and the plurality of pen receiving electrodes SRx0, SRx1, . . . , SRx4, and SRx5. The X-axis sensing may be performed by one kind of electrodes of the plurality of touch driving electrodes FTx0, FTx1, . . . , FTx8, and FTx9 and the plurality of pen driving electrodes STx0, STx1, . . . , STx8, and Stx9, and the Y-axis sensing may be performed by one kind of electrodes of the plurality of touch receiving electrodes FRx0, FRx1, . . . , FRx4, and FRx5 and the plurality of pen receiving electrodes SRx0, SRx1, . . . , SRx4, and SRx5.

In the <Table 3> above, the ‘magnitude of uplink signal’ represents a magnitude of the driving signal for driving the stylus pen. The ‘magnitude of downlink signal’ represents a magnitude of the stylus pen signal received from the stylus pen. The ‘stylus additional channel’ represents whether an additional channel is necessary for the stylus pen in addition to the touch sensing.

The electronic device illustrated in FIG. 13 may perform the proximity sensing using the sensor 100″. While the proximity sensing is performed, the controller 300 may control driving signals to be applied simultaneously to the plurality of touch driving electrodes FTx0, FTx1, . . . , FTx8, Ftx9 such that positive (+) driving signals are applied to upper touch driving electrodes FTx0, FTx1, . . . , FTx4, and negative (−) driving signals are applied to lower touch driving electrodes FTx5, FTx6, . . . , FTx9 among the plurality of touch driving electrodes FTx0, FTx1, . . . , FTx8, FTx9.

Also, the controller 300 may detect whether an object is in proximity based on the sensing signals output from the plurality of touch receiving electrodes FRx0, FRx1, . . . , FRx4, FRx5.

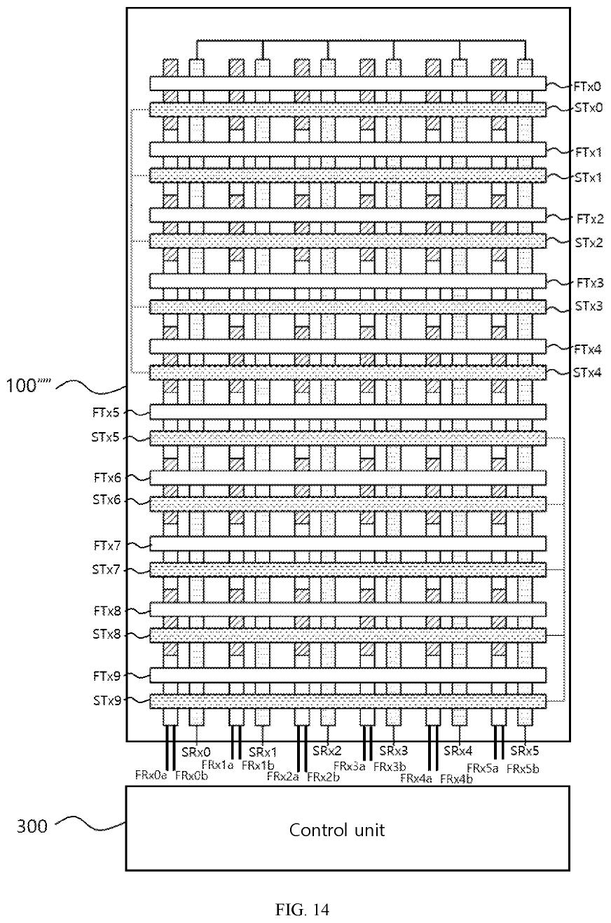

FIG. 14 is a schematic block diagram illustrating an electronic device according to another embodiment of the present invention.

The electronic device according to another embodiment of the present invention in FIG. 14 is different in a sensor 100″″′ from the electronic device in FIG. 4.

The sensor 100″″′ illustrated in FIG. 14 is the same as the sensor 100″″ illustrated in FIG. 13 except for a plurality of touch receiving electrodes.

Each of the plurality of touch receiving electrodes of the sensor 100″″′ illustrated in FIG. 14 includes a pair of a first receiving electrode unit FRx0a, FRx1a, . . . , FRx5a and a second receiving electrode unit FRx0b, FRx1b, . . . , FRx5b.

The first receiving electrode units FRx0a, FRx1a, . . . , FRx5a and the second receiving electrode units FRx0b, FRx1b, . . . , FRx5b may be alternately arranged one by one along the longitudinal direction.

The first receiving electrode units FRx0a, FRx1a, . . . , FRx5a may form a mutual capacitance with some driving electrodes FTx0, FTx2, FTx4, FTx6, and FTx8 among the plurality of touch driving electrodes FTx0, FTx1, . . . , FTx8, and FTx9 or be disposed directly adjacent thereto and may form little mutual capacitance with remaining driving electrodes FTx1, FTx3, FTx5, FTx7, and FTx9 or be spaced apart therefrom.

The second receiving electrode units FRx0b, FRx1b, . . . , FRx5b may form a mutual capacitance with the remaining driving electrodes FTx1, FTx3, FTx5, FTx7, and FTx9 of the plurality of touch driving electrodes FTx0, FTx1, . . . , FTx8, and FTx9 or be disposed directly adjacent thereto and may form little mutual capacitance with the some driving electrodes FTx0, FTx2, FTx4, FTx6, and FTx8 or be spaced apart therefrom.

The electronic device in FIG. 14 may perform the proximity sensing by using the sensor 100″″′. While the proximity sensing is performed, the controller 300 may control driving signals to be applied simultaneously to the plurality of touch driving electrodes FTx0, FTx1, . . . , FTx8, Ftx9 such that positive (+) driving signals are applied to upper touch driving electrodes FTx0, FTx1, . . . , FTx4, and negative (−) driving signals are applied to lower touch driving electrodes FTx5, FTx6, . . . , FTx9 among the plurality of touch driving electrodes FTx0, FTx1, . . . , FTx8, FTx9.

Also, the control unit 300 may perform differential processing on two sensing signals output from the pair of receiving electrode units of each touch receiving electrode to remove noises (such as the display noise and the LGM noise) generated during the proximity sensing, thereby improving sensitivity of the proximity sensing.

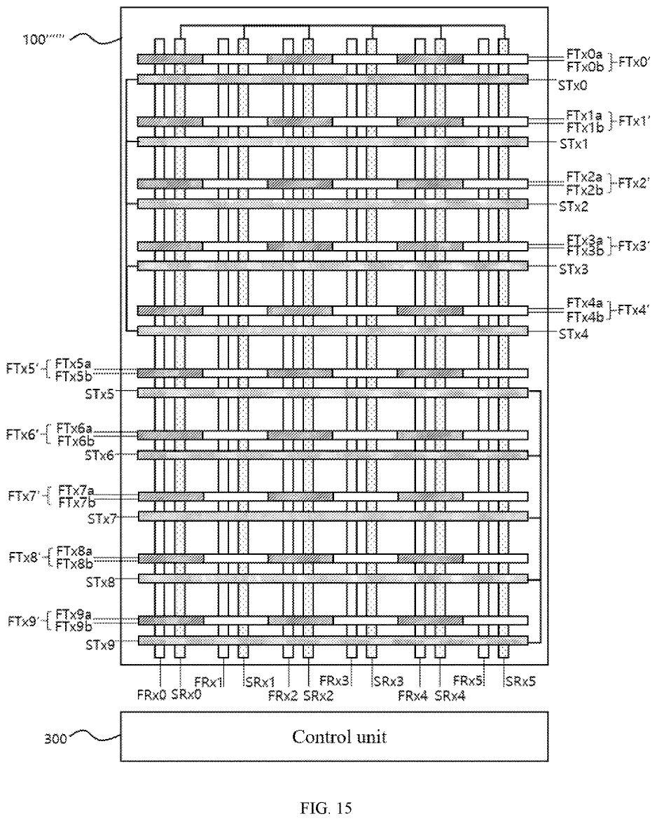

FIG. 15 is a schematic block diagram illustrating an electronic device according to another embodiment of the present invention.

The electronic device according to another embodiment of the present invention in FIG. 15 is different in a sensor 100″″″ from the electronic device in FIG. 4.

The sensor 100″″″ illustrated in FIG. 15 is different in a plurality of driving electrodes FTx0′, FTx1′, . . . , FTx8′, and FTx9′ from the sensor 100″″ illustrated in FIG. 13, while the remaining components are the same as each other.

Each of the plurality of touch driving electrodes of the sensor 100″″″ illustrated in FIG. 15 includes a pair of a first driving electrode unit FTx0a, FTx1a, . . . , FTx9a and a second driving electrode unit FTx0b, FTx1b, . . . , FTx9b.

The first driving electrode units FTx0a, FTx1a, . . . , FTx9a and the second driving electrode units FTx0b, FTx1b, . . . , FTx9b may be alternately arranged one by one in the minor axis direction.

The first driving electrode units FTx0a, FTx1a, . . . , FTx9a may form a mutual capacitance with some receiving electrodes FRx0, FRx2, and FRx4 among the plurality of touch driving electrodes FRx0, FRx1, . . . , FRx4, and FRx5 or be disposed directly adjacent thereto and may form little mutual capacitance with remaining receiving electrodes FRx1, FRx3, and FRx5 or be spaced apart therefrom.

The second driving electrode units FTx0b, FTx1b, . . . , FTx9b may form a mutual capacitance with the remaining receiving electrodes FRx1, FRx3, and FRx5 among the plurality of receiving electrodes FTx0, FTx1, . . . , FRx4, and FRx5 or be disposed directly adjacent thereto and may form little mutual capacitance with the some driving electrodes FRx0, FRx2, and FRx4 or be spaced apart therefrom.

A first driving signal and a second driving signal may be simultaneously applied to the pair of first and second driving electrode units of each touch driving electrode FTx0′, FTx1′, . . . , FTx8′, and FTx9′. Here, each of the first driving signal and the second driving signal may be a pulse signal or a sine signal having a phase shifted by 180°.

The electronic device illustrated in FIG. 15 may perform the proximity sensing by using the sensor 100″″″. While the proximity sensing is performed, the control unit 300 may control driving signals to be applied simultaneously to the plurality of touch driving electrodes FTx0′, FTx1′, . . . , FTx8′, and FTx9′ such that positive (+) driving signals are applied to upper touch driving electrodes FTx0′, FTx1′, . . . , FTx4′ among the plurality of touch driving electrodes FTx0′, FTx1′, . . . , FTx8′, and FTx9′, and negative (−) driving signals are applied to lower touch driving electrodes FTx5′, FTx6′, . . . , FTx9′.

Also, the control unit 300 may detect whether an object is in proximity based on the sensing signals output from the respective touch receiving electrodes FRx0, FRx1, . . . , FRx5.

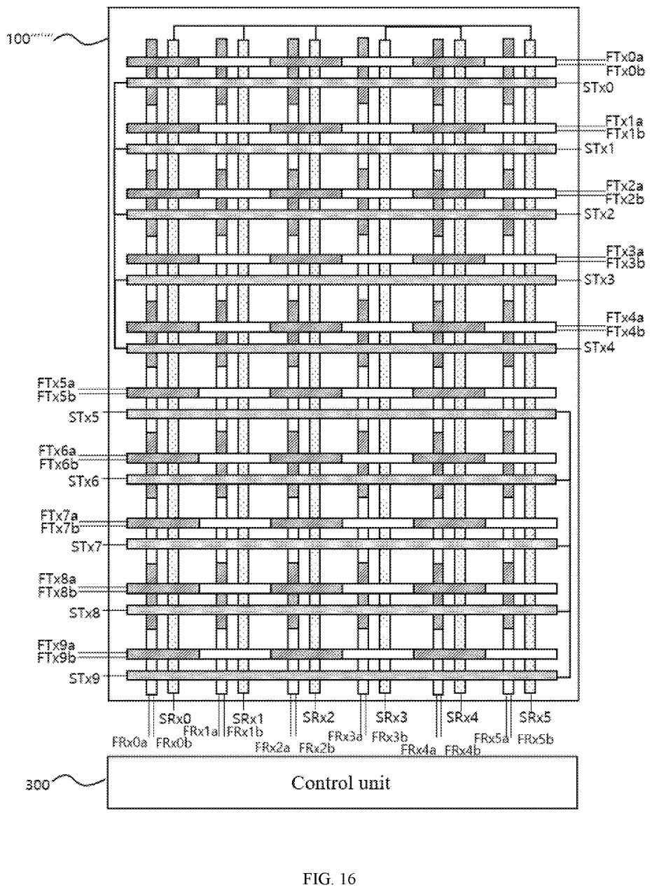

FIG. 16 is a schematic block diagram illustrating an electronic according to another embodiment of the present invention.

The electronic device according to another embodiment of the present invention in FIG. 16 is different in a sensor 100″″″′ from the electronic device in FIG. 4.

The sensor 100″″″′ illustrated in FIG. 16 is different in a plurality of touch driving electrodes and a plurality of touch receiving electrodes from the sensor 100″″ illustrated in FIG. 13.

Each of the plurality of touch receiving electrodes of the sensor 100″″″″′ illustrated in FIG. 16 includes a pair of a first receiving electrode unit FRx0a, FRx1a, . . . , FRx5a and a second receiving electrode unit FRx0b, FRx1b, . . . , FRx5b.

Each of the plurality of touch driving electrodes includes a pair of a first driving electrode unit FTx0a, FTx1a, . . . , FTx9a and a second driving electrode unit FTx0b, FTx1b, . . . , FTx9b. The electronic device illustrated in FIG. 16 may perform the proximity sensing by using the sensor 100″″″′. While the proximity sensing is performed, the control unit 300 may control driving signals to be applied simultaneously to the plurality of touch driving electrodes such that positive (+) driving signals are applied to upper touch driving electrodes among the plurality of touch driving electrodes, and negative (−) driving signals are applied to lower touch driving electrodes.

Also, the control unit 300 may detect whether an object is in proximity based on differential signals obtained by performing differential processing on two sensing signals output from the pair of receiving electrode units of each touch receiving electrode.

Features, structures, and effects described in the above embodiments are incorporated into at least one embodiment of the present disclosure, but are not limited to only one embodiment. Moreover, features, structures, and effects exemplified in one embodiment may easily be combined and modified for another embodiment by those skilled in the art. Therefore, these combinations and modifications should be construed as falling within the scope of the present disclosure.

Although embodiments have been described with reference to a number of illustrative embodiments thereof, it should be understood that numerous other modifications and embodiments may be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An electronic device comprising:
a sensor comprising a plurality of driving electrodes and a plurality of receiving electrodes arranged to intersect the plurality of driving electrodes; and
a control unit configured to simultaneously drive the plurality of driving electrodes during a predetermined period of time for proximity sensing on a touch screen, and to detect whether an object is in proximity to the touch screen based on sensing signals from the plurality of receiving electrodes,
wherein the control unit is configured such that a positive (+) driving signal is applied to some driving electrodes of the plurality of driving electrodes, and a negative (−) driving signal is applied to remaining driving electrodes of the plurality of driving electrodes.

2. The electronic device of claim 1, wherein the touch screen has a length in a vertical direction, which is greater than a length in a horizontal direction, and
the driving electrodes are arranged in the horizontal direction below the touch screen.

3. The electronic device of claim 2, wherein the touch screen comprises an upper touch screen and a lower touch screen,
the some driving electrodes are arranged below the upper touch screen, and
the remaining driving electrodes are arranged below the lower touch screen.

4. The electronic device of claim 2, wherein a ratio between the number of the some driving electrodes and the number of the remaining driving electrodes is 1:1.

5. The electronic device of claim 2, wherein a ratio between the number of the some driving electrodes and the number of the remaining driving electrodes is 4:6 or 6:4.

6. The electronic device of claim 1, wherein each of the plurality of receiving electrodes comprises a first receiving electrode unit and a second receiving electrode unit, and
the control unit is configured to detect whether an object is in proximity based on a differential signal obtained by differentially amplifying a first sensing signal output from the first receiving electrode unit and a second sensing signal output from the second receiving electrode unit of each of the receiving electrodes.

7. The electronic device of claim 1, wherein each of the plurality of receiving electrodes comprises a first receiving electrode unit configured to output a first sensing signal and a second receiving electrode unit configured to output a second sensing signal,
the first receiving electrode unit and the second receiving electrode unit are alternately arranged along one direction,
the first receiving electrode unit is disposed directly adjacent to odd-numbered driving electrodes and disposed not directly adjacent to even-numbered driving electrodes among the plurality of driving electrodes along another direction, and
the second receiving electrode unit is disposed directly adjacent to the even-numbered driving electrodes and disposed not directly adjacent to the odd-numbered driving electrodes.

8. The electronic device of claim 1, wherein each of the plurality of driving electrodes comprises a first driving electrode unit and a second driving electrode unit,
the first driving electrode unit is disposed directly adjacent to some receiving electrodes and disposed not directly adjacent to the remaining receiving electrodes among the plurality of the receiving electrodes, and
the second driving electrode unit is disposed directly adjacent to the remaining receiving electrodes and disposed not directly adjacent to the some receiving electrodes.

9. The electronic device of claim 8, wherein each of the plurality of receiving electrodes comprises a first receiving electrode unit and a second receiving electrode unit, and
the control unit is configured to detect whether an object is in proximity based on a differential signal obtained by differentially amplifying a first sensing signal output from the first receiving electrode unit and a second sensing signal output from the second receiving electrode unit of each of the receiving electrodes.

10. The electronic device of claim 1, further comprising:
a plurality of first pen electrodes disposed adjacent to the plurality of driving electrodes, respectively; and
a plurality of second pen electrodes disposed adjacent to the plurality of receiving electrodes, respectively,
wherein one ends of the plurality of first pen electrodes are electrically connected to each other, and
one ends of the plurality of second pen electrodes are electrically connected to each other.

11. The electronic device of claim 10, wherein each of the plurality of receiving electrodes comprises a first receiving electrode unit configured to output a first sensing signal and a second receiving electrode unit configured to output a second detection signal,
the first receiving electrode unit and the second receiving electrode unit are alternately arranged along one direction,
the first receiving electrode unit is disposed directly adjacent to odd-numbered driving electrodes and disposed not directly adjacent to even-numbered driving electrodes among the plurality of driving electrodes along another direction, and
the second receiving electrode unit is disposed directly adjacent to the even-numbered driving electrodes and disposed not directly adjacent to the odd-numbered driving electrodes.

12. The electronic device of claim 10, wherein each of the plurality of driving electrodes comprises a first driving electrode unit and a second driving electrode unit,
the first driving electrode unit is disposed directly adjacent to some receiving electrodes and disposed not directly adjacent to the remaining receiving electrodes among the plurality of the receiving electrodes, and
the second driving electrode unit is disposed directly adjacent to the remaining receiving electrodes and disposed not directly adjacent to the some receiving electrodes.

13. The electronic device of claim 12, wherein each of the plurality of receiving electrodes comprises a first receiving electrode unit and a second receiving electrode unit, and
the control unit is configured to detect whether an object is in proximity based on a differential signal obtained by differentially amplifying a first sensing signal output from the first receiving electrode unit and a second sensing signal output from the second receiving electrode unit of each of the receiving electrodes.

14. The electronic device of claim 1, further comprising a display panel,
wherein the sensor is disposed in the display panel.

15. The electronic device of claim 1, further comprising a display panel;
wherein the sensor is disposed on or below the display panel.

16. A proximity sensing method of a control unit of an electronic device comprising a sensor comprising a plurality of driving electrodes and a plurality of receiving electrodes arranged to intersect the plurality of driving electrodes and the control unit configured to control the sensor, the proximity sensing method comprising:
controlling the plurality of driving electrodes to be driven simultaneously during a predetermined period of time for proximity sensing on the sensor such that a positive (+) driving signal is applied to some driving electrodes and a negative (−) driving signal is applied to the remaining driving electrodes among the plurality of driving electrodes;
receiving sensing signals from the plurality of receiving electrodes; and
detecting whether an object is in proximity to the sensor based on the sensing signals.
